(19) United States
(12) Patent Application Publication
(10) Pub. No.: US 2025/0285989 A1
(43) Pub. Date: Sep. 11, 2025

(54) SEMICONDUCTOR DEVICE, ELECTRONIC SYSTEM INCLUDING THE SAME AND METHOD FOR FABRICATING THE SAME

(71) Applicant: Samsung Electronics Co., Ltd., Suwon-si (KR)

(72) Inventors: WONHYEOK JO, Suwon-si (KR); BYEONG-HWAN SON, Suwon-si (KR)

(21) Appl. No.: 18/939,743

(22) Filed: Nov. 7, 2024

(30) Foreign Application Priority Data
Mar. 7, 2024 (KR) 10-2024-0032531

(51) Int. Cl. H01L 23/544; H10B 41/10; H10B 41/27; H10B 41/41; H10B 43/10; H10B 43/27; H10B 43/40

(52) U.S. Cl. CPC H01L 23/544; H10B 41/10; H10B 41/27; H10B 41/41; H10B 43/10; H10B 43/27; H10B 43/40; H01L 2223/54426

(57) ABSTRACT

A semiconductor device may include a substrate including a chip region and an edge region around the chip region, an alignment key disposed in the edge region of the substrate, a stack including conductive patterns and interlayer insulating layers, which are vertically and alternatingly stacked on the chip region of the substrate, the stack having a first staircase structure, and a dummy mold structure including dummy insulating layers and sacrificial patterns, which are vertically and alternatingly stacked on the edge region of the substrate, the dummy mold structure overlapping with the alignment key and having a second staircase structure. The dummy mold structure May have substantially the same height as the stack, when measured from the substrate.

### CROSS-REFERENCE TO RELATED APPLICATIONS

This U.S. non-provisional patent application claims priority under 35 U.S.C. § 119 to Korean Patent Application No. 10-2024-0032531, filed on Mar. 7, 2024, in the Korean Intellectual Property Office, the entire contents of which are hereby incorporated by reference.

### BACKGROUND

The present disclosure relates to a semiconductor device, an electronic system including the same, and a method of fabricating the same.

The data storage demands of electronic systems are ever-increasing. Accordingly, approaches are being developed to increase the data storage capacities of semiconductor devices used for data storage in such systems. For example, semiconductor devices in which memory cells are three-dimensionally arranged are being suggested.

### SUMMARY

An embodiment of the inventive concept provides a highly reliable and highly integrated semiconductor device and an electronic system including the same.

An embodiment of the inventive concept provides a method capable of reducing process defects in a process of fabricating a semiconductor device.

According to an embodiment of the inventive concept, a semiconductor device may include a substrate including a chip region and an edge region around the chip region, an alignment key disposed in the edge region of the substrate, a stack including conductive patterns and interlayer insulating layers, which are vertically and alternatingly stacked on the chip region of the substrate, the stack having a first staircase structure, and a dummy mold structure including dummy insulating layers and sacrificial patterns, which are vertically and alternatingly stacked on the edge region of the substrate, the dummy mold structure overlapping with the alignment key and having a second staircase structure. The dummy mold structure may have substantially the same height as the stack, when measured from the substrate.

According to an embodiment of the inventive concept, an electronic system may include a semiconductor device including a substrate including a chip region and an edge region around the chip region, a stack including conductive patterns and interlayer insulating layers vertically and alternatingly stacked on the chip region of the substrate, a dummy mold structure including dummy insulating layers and sacrificial patterns vertically and alternatingly stacked on the edge region of the substrate, and an input/output pad electrically connected to a peripheral circuit, and a controller, which is electrically connected to the semiconductor device through the input/output pad and is used to control the semiconductor device. The stack may have a first staircase structure, and the dummy mold structure may have a second staircase structure. The dummy mold structure may have a height, which is substantially equal to the stack, when measured from the substrate.

According to an embodiment of the inventive concept, a method of fabricating a semiconductor device may include alternatingly stacking interlayer insulating layers and sacrificial layers on a substrate to form a layered structure, the substrate including a chip region and an edge region around the chip region, the substrate comprising an alignment key provided in the edge region, and patterning the layered structure to form a mold structure on the chip region and a dummy mold structure on the edge region. The patterning of the layered structure may include repeating a patterning process using the alignment key, and the mold structure may have a first staircase structure. The dummy mold structure may be overlapped with the alignment key and may have a second staircase structure, and the dummy mold structure may have substantially the same height as the mold structure, when measured from the substrate.

### BRIEF DESCRIPTION OF THE DRAWINGS

FIG. 1 is a diagram illustrating a semiconductor substrate, on which semiconductor devices according to an embodiment of the inventive concept are integrated.

FIG. 2 is a plan view illustrating a semiconductor device according to an embodiment of the inventive concept.

FIG. 3 is a sectional view, which are taken along lines I-I′, II-II′, and III-III′ of FIG. 2 to illustrate a semiconductor device according to an embodiment of the inventive concept.

FIGS. 4A, 4B, and 5 to 16 are sectional views illustrating a method of fabricating a semiconductor device, according to an embodiment of the inventive concept.

FIG. 17 is a sectional view illustrating a semiconductor device according to an embodiment of the inventive concept.

FIGS. 18 and 19 are sectional views illustrating a method of fabricating a semiconductor device, according to an embodiment of the inventive concept.

FIG. 20 is a diagram schematically illustrating an electronic system including a semiconductor device according to an embodiment of the inventive concept.

FIG. 21 is a perspective view schematically illustrating an electronic system, which includes a semiconductor device according to an embodiment of the inventive concept.

FIGS. 22 and 23 are sectional views schematically illustrating semiconductor packages, according to some embodiments of the inventive concept.

### DETAILED DESCRIPTION

Throughout the specification, when a component is described as “including” a particular element or group of elements, it is to be understood that either the component is formed of only the element or the group of elements, or the element or group of elements may be combined with additional elements to form the component, unless the context indicates otherwise. The term “consisting of,” on the other hand, indicates that a component is formed only of the element(s) listed.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact. Components described as being “electrically connected” are configured such that an electrical signal can be transferred from one component to the other (although such electrical signal may be attenuated in strength as it is transferred and may be selectively transferred).

The present disclosure now will be described more fully hereinafter with reference to the accompanying drawings, in which various embodiments are shown. The invention may, however, be embodied in many different forms and should not be construed as limited to the example embodiments set forth herein. These example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

Example embodiments of the inventive concepts will now be described more fully with reference to the accompanying drawings, in which example embodiments are shown.

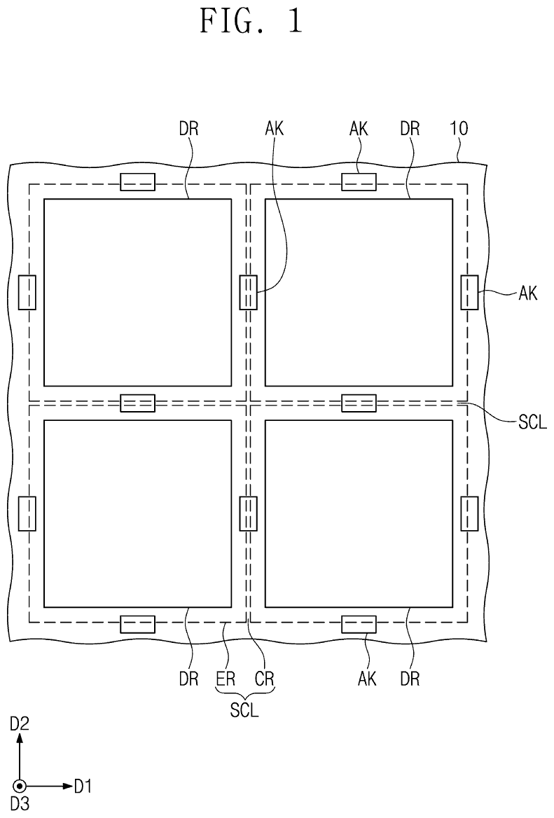

FIG. 1 is a diagram illustrating a semiconductor substrate, on which semiconductor devices according to an embodiment of the inventive concept are integrated. A semiconductor device, as described herein, may refer to an integrated circuit formed on a substrate, either in wafer form (e.g., before being singulated) or in die form (e.g., after being singulated).

Referring to FIG. 1, a semiconductor substrate 10 (e.g., a semiconductor wafer) may include chip regions DR, on which semiconductor chips are respectively formed, and a scribe line region SCL between the chip regions DR. The chip regions DR may be two-dimensionally arranged in first and second directions D1 and D2 that cross each other. Each of the chip regions DR may be enclosed by the scribe line region SCL. That is, the scribe line region SCL may be disposed between chip regions DR that are adjacent to each other in the first direction D1, and between chip regions DR that are adjacent to each other in the second direction D2.

The semiconductor substrate 10 may be a bulk silicon wafer, a silicon-on-insulator (SOI) wafer, a germanium wafer, a germanium-on-insulator (GOI) wafer, a silicon-germanium wafer, or a substrate including an epitaxial layer formed by a selective epitaxial growth (SEG) process.

In an embodiment, the semiconductor device may be fabricated to include memory cells, which are three-dimensionally arranged on each of the chip regions DR of the semiconductor substrate 10.

Monitoring patterns, which are used to monitor each of semiconductor fabrication processes, may be provided on the scribe line region SCL of the semiconductor substrate 10. The monitoring patterns may include alignment keys AK, which are used as the reference for the pattern or wafer alignment in the semiconductor fabrication processes, overlay keys, which are used to examine an overlapping accuracy between upper and lower patterns, and measurement patterns, which are used to measure geometric features (e.g., thickness and linewidth) of formed patterns. The shape of the monitoring patterns may vary depending on position. The alignment keys AK may be formed at left and right sides of the chip regions DR in the first direction D1 and may be formed at top and bottom sides of the chip regions DR in the second direction D2.

The scribe line region SCL may include a plurality of first scribe line regions, which extend in the first direction D1, and a plurality of second scribe line regions, which extend in the second direction D2 to cross the first scribe line regions. The scribe line region SCL may include a cutting region CR, which is cut by a sawing or dicing machine, and edge regions ER between the cutting region CR and the chip regions DR. Each edge regions ER may enclose a respective chip region DR.

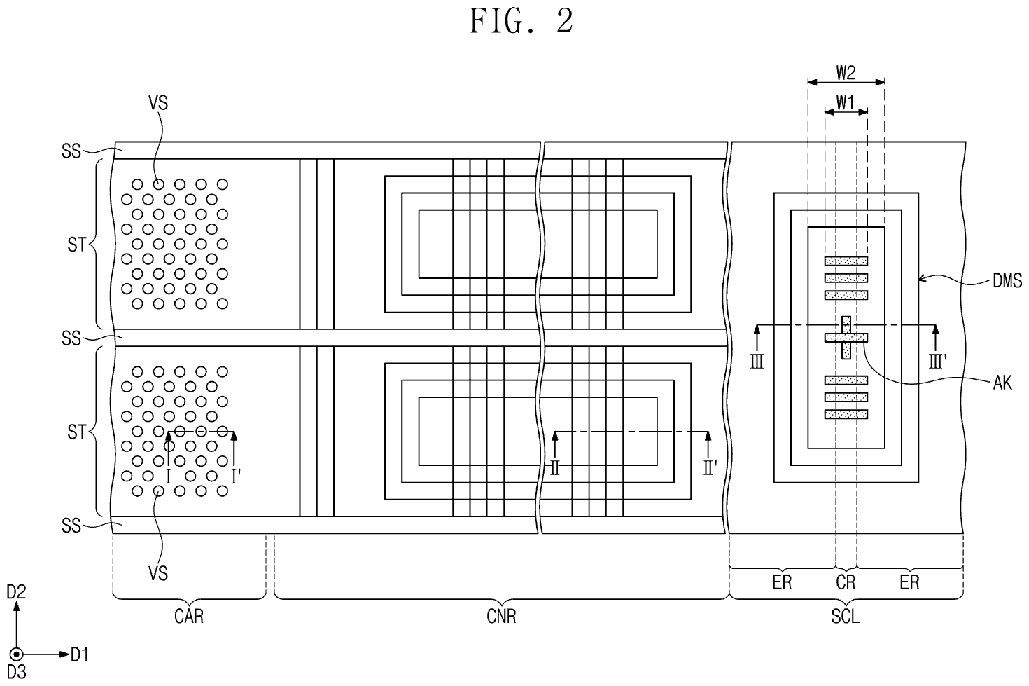

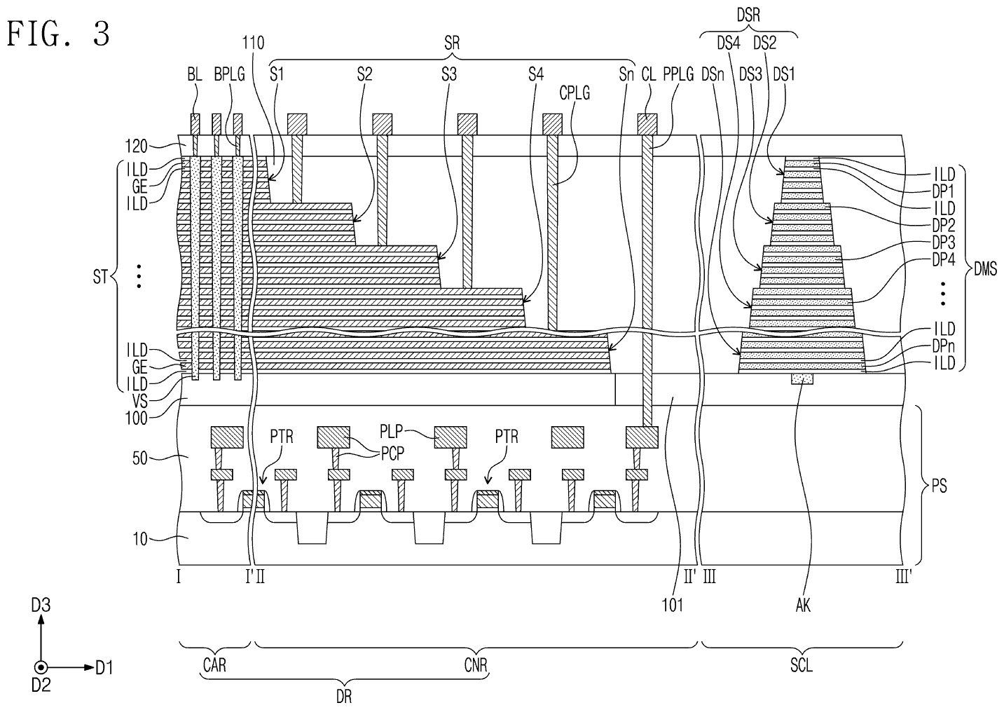

FIG. 2 is a plan view illustrating a semiconductor device according to an embodiment of the inventive concept. FIG. 3 is a sectional view, which are taken along lines I-I′, II-II′, and III-III′ of FIG. 2 to illustrate a semiconductor device according to an embodiment of the inventive concept.

Referring to FIGS. 2 and 3, the semiconductor device may include a peripheral circuit structure PS on the semiconductor substrate 10 and a cell array structure CS on the peripheral circuit structure PS.

The semiconductor substrate 10 may include the chip regions DR (e.g., of FIG. 1) and the scribe line region SCL, as previously described with reference to FIG. 1. In the semiconductor substrate 10, each of the chip regions DR (e.g., of FIG. 1) may include a cell array region CAR and a connection region CNR adjacent to the cell array region CAR. The semiconductor substrate 10 may be a silicon substrate, such as a silicon wafer.

The peripheral circuit structure PS may include peripheral circuits PTR, which are integrated on a top surface of the semiconductor substrate 10, and a peripheral circuit insulating layer 50, which is provided to cover the peripheral circuits PTR.

The peripheral circuits PTR may include row and column decoders, a page buffer, a control circuit, and so forth. In more detail, the peripheral circuits PTR may include NMOS and PMOS transistors. Peripheral circuit interconnection lines may be electrically connected to the peripheral circuits PTR through peripheral contact plugs PCP.

The peripheral circuit insulating layer 50 may be provided on the semiconductor substrate 10. The peripheral circuit insulating layer 50 on the semiconductor substrate 10 may cover the peripheral circuits PTR, the peripheral contact plugs PCP, and peripheral circuit interconnection lines PLP. The peripheral contact plugs PCP and the peripheral circuit interconnection lines PLP may be electrically connected to the peripheral circuits PTR.

The peripheral circuit insulating layer 50 may include a plurality of vertically-stacked insulating layers. For example, the peripheral circuit insulating layer 50 may include a silicon oxide layer, a silicon nitride layer, a silicon oxynitride layer, and/or a low-k dielectric layer. A substrate 100 may be disposed on a top surface of the peripheral circuit insulating layer

50. The substrate 100 may be formed of or include at least one of semiconductor, insulating, or conductive materials. The substrate 100 may be formed of or include a semiconductor material, which is doped to have a first conductivity type (e.g., n-type), and/or an undoped or intrinsic semiconductor material. For example, the substrate 100 may be formed of or include at least one of doped polysilicon, undoped polysilicon, metallic materials, conductive metal nitride materials, conductive metal silicide materials, or conductive metal oxide materials. The substrate 100 may have one of single-crystalline, amorphous, and polycrystalline structures.

The substrate 100 may include various alignment keys AK, which are provided on the scribe line region SCL and are used for a photolithography process. For example, the alignment keys AK may be formed in cross, bar, rectangle, closed-curve, and cramp shapes.

Although the alignment keys AK on the scribe line region SCL are illustrated to be formed in the substrate 100, the inventive concept is not limited to this example. In an embodiment, the alignment keys AK may be disposed in the peripheral circuit insulating layer 50 of the peripheral circuit structure PS. In some examples, with respect to a third direction D3 that is perpendicular to the first and second directions D1 and D2, the alignment keys AK may be placed at the same level as the peripheral circuit interconnection lines PLP of the peripheral circuit structure PS.

A plurality of stacks ST may be disposed on the chip region DR of the substrate 100. The stacks ST may extend in the first direction D1 and may be spaced apart from each other in the second direction D2. A separation structure SS may be disposed between adjacent stacks ST. On the substrate 100, the separation structures SS may extend parallel to the stacks ST in the first direction D1.

Each stack ST may include conductive patterns GE and interlayer insulating layers ILD, which are alternatingly stacked in the third direction D3. In FIG. 3, the third direction D3 is a vertical direction, and thus the conductive patterns GE and the interlayer insulating layers ILD are alternatingly stacked vertically. The conductive patterns GE may be formed of or include at least one of, for example, doped semiconductor materials (e.g., doped silicon), metallic materials (e.g., tungsten, copper, and aluminum), conductive metal nitride materials (e.g., titanium nitride and tantalum nitride), or transition metals (e.g., titanium and tantalum). The interlayer insulating layers ILD may include a silicon oxide layer and/or a low-k dielectric layer. The conductive patterns GE may include pad portions, respectively, in the connection region CNR, and cell contact plugs CPLG may be coupled to the pad portions of the conductive patterns GE, respectively.

The stacks ST may extend from the cell array region CAR to the connection region CNR in the first direction D1 and may have a first staircase structure SR in the connection region CNR.

The first staircase structure SR of the stack ST may extend along the connection region CNR in the first direction D1. In an embodiment, the stack ST may also have a staircase structure that extends in the second direction D2.

The first staircase structure SR may be composed of first to n-th stairs S1 to Sn. In an embodiment, the first stair S1 (e.g., step) may be the topmost stair (e.g., step) of the first staircase structure SR, and the n-th stair Sn (e.g., step) may be the bottommost stair (e.g., step) of the first staircase structure SR. Each of the first to n-th stairs S1 to Sn may include at least two conductive patterns GE, and may have a first height. As an example, each of the first to n-th stairs S1 to Sn may include four conductive patterns GE. Each of the first to n-th stairs S1 to Sn may include sub-stairs, each of which may include only one conductive pattern GE among the conductive patterns GE that form the stair. The first stair S1 may be formed to have a particular inclination angle with respect to a top surface of the substrate 100. In an embodiment, all of the first to n-th stairs S1 to Sn may have substantially the same inclination angle with respect to the top surface of the substrate 100. Side surfaces of the first to n-th stairs S1 to Sn may be horizontally spaced apart from each other by a first distance in the first direction D1.

A plurality of vertical structures VS may be provided in the cell array region CAR and may vertically penetrate the stack ST in the cell array region CAR. When viewed in a plan view (as in FIG. 2), the vertical structures VS may be arranged in a specific direction or in a zigzag shape. Vertical structures VS may also be provided in the connection region CNR and may vertically penetrate the stack ST in the connection region CNR. In the connection region CNR, the vertical structures VS may penetrate the pad portions of the conductive patterns GE. Each of the vertical structures VS may include a vertical semiconductor pattern and a data storage pattern, which is provided to enclose a side surface of the vertical semiconductor pattern. Here, the vertical semiconductor pattern may be formed of or include at least one semiconductor material (e.g., at least one of silicon (Si) and germanium (Ge)).

A dummy mold structure DMS may be disposed on the scribe line region SCL of the substrate 100. The dummy mold structure DMS may also be described as a scribe line region mold structure, and may include a stack of layers that are not electrically connected to any memory cells or peripheral circuit transistors or to any other circuits. A top surface of the dummy mold structure DMS may be located at the same vertical level (the same level in the direction D3 in FIG. 3) as a top surface of the stack ST. The dummy mold structure DMS may include dummy sacrificial patterns DP1 to DPn, which are disposed between interlayer insulating layers ILD. The dummy sacrificial patterns DPI to DPn may be formed of or include an insulating material different from the interlayer insulating layers ILD. In an embodiment, dummy sacrificial patterns DSL may be formed of or include at least one of silicon nitride, silicon oxynitride, or silicon germanium.

The dummy mold structure DMS may have a second staircase structure DSR. The second staircase structure DSR may be composed of first to n-th dummy stairs DS1 to DSn, and in an embodiment, the first to n-th dummy stairs DS1 to DSn may be located at the same vertical levels (the same levels in the direction D3 in FIG. 3) as the first to n-th stairs S1 to Sn, respectively. In an embodiment, the first dummy stair DS1 may be the topmost dummy stair of the second staircase structure DSR, and the n-th dummy stair DSn may be the bottommost dummy stair.

The dummy mold structure DMS may be overlapped with the alignment keys AK of the scribe line region SCL. The dummy mold structure DMS may have the smallest width (e.g., W2) at its top level, and the smallest width W2 of the dummy mold structure DMS may be larger than a width W1 of the alignment key AK.

Each of the first to n-th dummy stairs DS1 to DSn may include at least two dummy sacrificial patterns, and may have a second height. Here, the second height may be substantially equal to the first height of each of the first to n-th stairs S1 to Sn. An inclination angle of each of the first to n-th dummy stairs DS1 to DSn with respect to the top surface of the substrate 100 may be substantially equal to the inclination angle of each of the first to n-th stairs S1 to Sn. Side surfaces of the first to n-th dummy stairs DS1 to DSn may be horizontally spaced apart from each other by a second distance in the first direction D1. The second distance may be smaller than the first distance between the side surfaces of the first to n-th stairs S1 to Sn.

An insulating gapfill layer 110 may cover the first staircase structure SR of the stack ST and the second staircase structure DSR of the dummy mold structure DMS. The insulating gapfill layer 110 may have a substantially flat top surface. The insulating gapfill layer 110 may include a single insulating layer or a plurality of stacked insulating layers.

A first planarization insulating layer 120 may be provided on the stack ST to cover top surfaces of the vertical structures VS.

The separation structures SS may be provided on the substrate 100 and may penetrate the first planarization insulating layer 120. Each of the separation structures SS may include an insulating layer covering the side surface of at least one stack ST. Each of the separation structures SS may have a single- or multi-layered structure and may separate adjacent stacks ST from each other.

Bit lines BL may be disposed on the first planarization insulating layer 120 in the cell array region CAR, and although they are omitted from the plan view, the bit lines BL may extend in the second direction D2 to cross the stack ST. The bit lines BL may be electrically connected to the vertical structures VS through bit line contact plugs BPLG.

The cell contact plugs CPLG may be provided to penetrate the first planarization insulating layer 120 and the insulating gapfill layer 110 and may be coupled to respective end portions of the conductive patterns GE. The smaller the horizontal distance from the cell contact plug CPLG to the cell array region CAR, the smaller may be the vertical length of the cell contact plug CPLG. The top surfaces of the cell contact plugs CPLG may be substantially coplanar with each other.

Peripheral contact plugs PPLG may be provided in the connection region CNR to penetrate the first planarization insulating layer 120, the insulating gapfill layer 110, and the substrate 100, and may be connected to the peripheral circuit interconnection line PLP. The peripheral contact plugs PPLG may be horizontally spaced apart from the stack ST. The peripheral circuit interconnection line PLP may electrically connect the peripheral contact plugs PPLG to the peripheral circuits PTR.

Conductive lines CL may be disposed on the first planarization insulating layer 120 of the connection region CNR and may be coupled to the cell contact plugs CPLG and the peripheral contact plugs PPLG. The conductive lines CL may electrically connect the peripheral contact plugs PPLG to the conductive patterns GE.

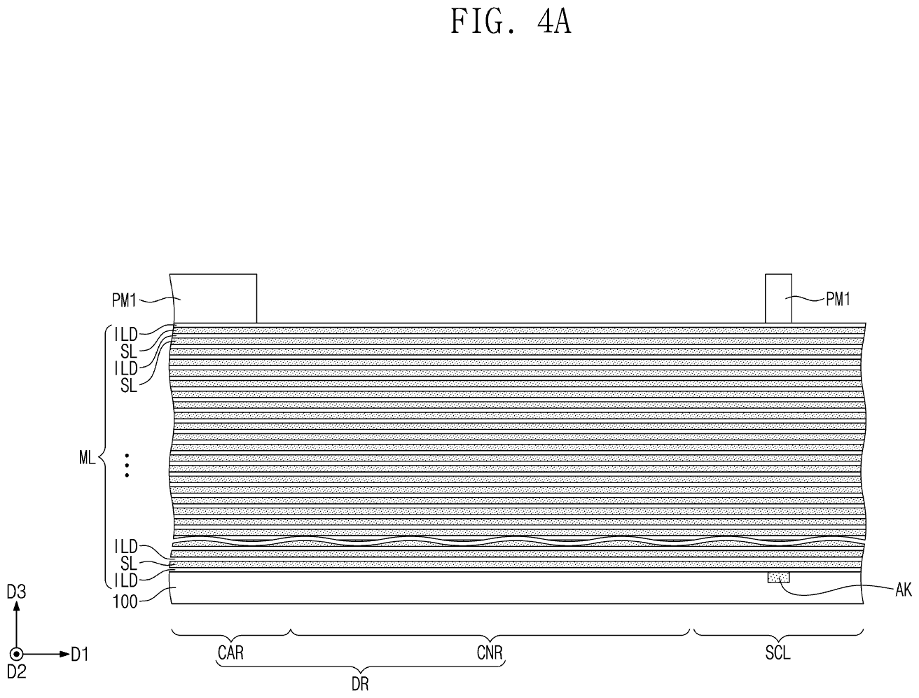

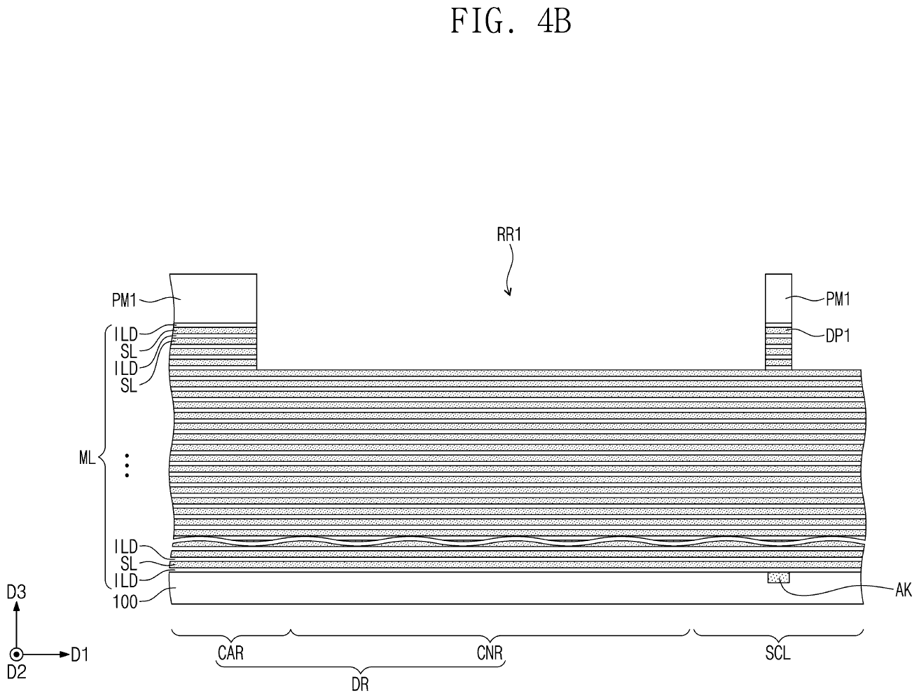

FIGS. 4A, 4B, and 5 to 16 are sectional views illustrating a method of fabricating a semiconductor device, according to an embodiment of the inventive concept.

Referring to FIG. 4A, a layered structure ML may be formed on the substrate 100 in the cell array region CAR, the connection region CNR, and the scribe line region SCL.

The connection region CNR may be adjacent to the cell array region CAR. The scribe line region SCL may be adjacent to the connection region CNR. As shown in FIG. 1 above, the scribe line region SCL may enclose the chip region DR.

As also shown in FIG. 1, the substrate 100 may include various alignment keys AK, which are provided in the scribe line region SCL and are used for a photolithography process. The alignment keys AK may be formed in various shapes, depending on their roles and or the photolithography system in use. For example, the alignment keys AK may be formed in cross, bar, rectangle, closed-curve, and cramp shapes.

FIG. 4A depicts an alignment key AK formed in the scribe line region SCL of the substrate 100. Although not shown in the drawings, the substrate 100 may include the peripheral circuit structure described above, and the alignment key AK may be formed simultaneously with the peripheral interconnection lines in the peripheral circuit structure, for example, of a metal or other material different from the material that forms the substrate 100.

The layered structure ML may include interlayer insulating layers ILD and sacrificial layers SL, which are vertically and alternatingly stacked on the substrate 100. Thus, the interlayer insulating layers ILD and the sacrificial layers SL may be alternatingly stacked in the third direction D3.

The layered structure ML may have a substantially uniform thickness in the cell array region CAR, the connection region CNR, and the scribe line region SCL.

The sacrificial layers SL may be formed of a material that can be etched with an etch selectivity with respect to the interlayer insulating layers ILD. In an embodiment, the sacrificial layers SL may be formed of an insulating material different from the interlayer insulating layers ILD. For example, the sacrificial layers SL may be formed of or include silicon nitride, and the interlayer insulating layers ILD may be formed of or include at least one of silicon oxide, silicon oxynitride, and/or low-k dielectric materials.

As shown in FIG. 4A, a first mask pattern PM1 may be formed on the layered structure ML.

The formation of the first mask pattern PM1 may include coating the layered structure with a first photoresist layer to cover the layered structure ML and performing exposing and developing processes on the first photoresist layer.

The first photoresist layer may be formed to uniformly coat the layered structure ML by using a spin coating process. In the spin coating process, the top of the layered structure ML may be coated with a photoresist material, and the substrate 100 may then be rotated at a high speed. In an embodiment, additional spin coating processes may be performed to form an organic planarization layer and an anti-reflection coating layer below the first photoresist layer and a top coating layer on the first photoresist layer.

A soft bake process may be performed, after the spin coating process. The soft bake process, which is called a ‘pre-bake process’, may be performed to remove an organic solvent left on the first photoresist layer and to firmly adhere the first photoresist layer to the top of the layered structure ML. The soft bake process may be performed at a relatively low temperature.

For alignment purposes, an optical inspection system may be used to determine the position of the alignment key AK before the exposing process for the first photoresist layer is performed.

During the exposing process for the first photoresist layer, a photomask or reticle may be aligned using the alignment key AK, and a portion of the first photoresist layer may be exposed to an electron beam or light, which is incident through the photomask.

The developing process may include spraying a developing solution onto first photoresist layer and spinning the substrate 100 to coat the top surface of the first photoresist layer with the developing solution or may include dipping the substrate 100 in the developing solution to coat the top surface of the first photoresist layer with the developing solution. As a result of the developing process, the exposed portion of the first photoresist layer may be removed. In some embodiments, an unexposed portion of the first photoresist layer may be removed, depending on the type of the first photoresist layer. In an embodiment, a cleaning process using an de-ionized water may be further performed to remove contaminating material (e.g., particles) after the developing process.

The first mask pattern PM1 may cover some portions of the layered structure ML while leaving other portions of the layered structure ML exposed. For example, as shown in FIG. 4A, the first mask pattern PM1 may leave a portion of the layered structure ML in the connection region CNR exposed. In an embodiment, the first mask pattern PM1 may include a first portion covering the cell array region CAR and the connection region CNR and a second portion covering a portion of the scribe line region SCL.

Next, an etching process may be applied using the first mask pattern PM1 as an etch mask. During the etching process, portions of the layered structure ML not covered by the first mask pattern PM1 may be subjected to etching. As shown in FIG. 4B, the etching process may result in the removal of material from the layered structure ML in the connection region CNR and uncovered portions of the scribe line region SCL. According to an embodiment of the inventive concept, the etching process may etch at least two sacrificial layers SL from the layered structure ML to form a first recessed region RR1.

A desired depth to be achieved for the first recessed region RR1 via the process of etching the layered structure ML may depend on a number of sacrificial layers SL to be removed. In an example, etching may be performed using the first mask pattern PM1 to etch at least two sacrificial layers SL from the layered structure ML. Removal of the at least two sacrificial layers SL from portions of the layered structure ML in the scribe line region SCL may form the first dummy sacrificial patterns DP1 in the scribe line region SCL.

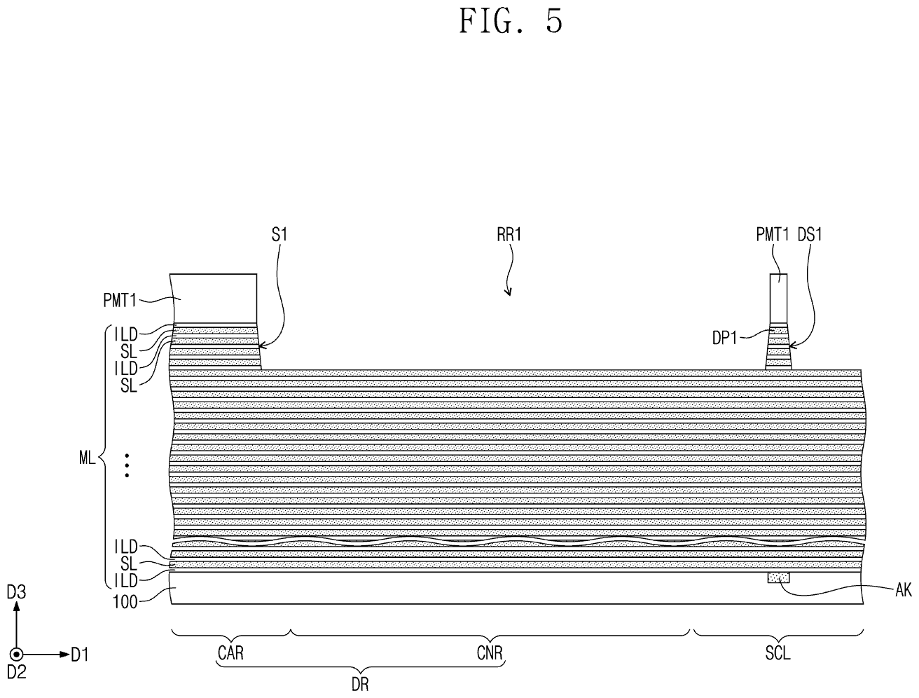

Referring to FIG. 5, a trimming process may be performed to reduce an area and a thickness of the first mask pattern PM1. As a result, a first trimming mask pattern PMT1 may be formed. The trimming process may be performed using, for example, an isotropic dry etching method or a wet etching method.

After the trimming process, a single-layer etching process may be performed using the first trimming mask pattern PMT1, and then, the trimming process and the single-layer etching process may be repeatedly and alternatingly performed. A number of repetitions of the single-layer etching process and the trimming process may be selected according to the intended depth of the first recessed region RR1 (i.e., the number of the sacrificial layers SL that are etched through the multi-layer etching process).

As a result of the repetition of the single-layer etching process, the first stair S1 may be formed in an upper portion of the layered structure ML, in the connection region CNR, and the first dummy stair DS1, which is defined by the first dummy sacrificial patterns DP1, may be formed in the scribe line region SCL.

The first stair S1 may include sub-stairs, each of which is composed of one sacrificial layer SL. The first stair S1 may have a sidewall that is inclined at a specific inclination angle to the top surface of the substrate 100. The first dummy stair DS1 may include sub-stairs, each of which is composed of one first dummy sacrificial pattern DP1. The first dummy stair DS1 may have a sidewall that is inclined at a specific inclination angle to the top surface of the substrate 100, and the inclination angle of the first dummy stair DS1 may be substantially equal to that of the first stair S1.

After the formation of the first stair S1 and the first dummy stair DS1, the first trimming mask pattern PMT1 may be removed through an ashing process and/or a strip process.

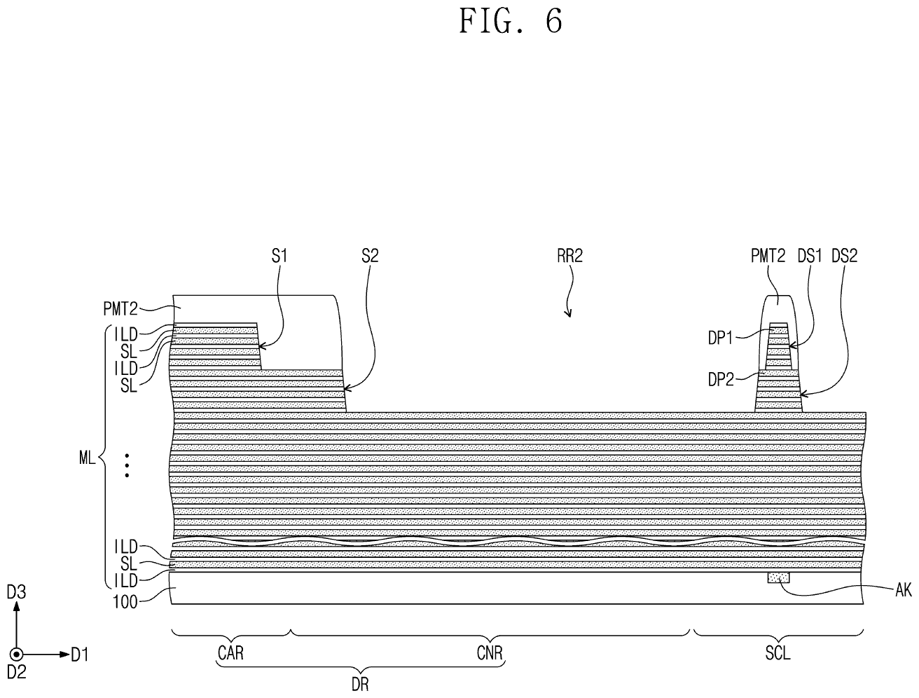

Referring to FIG. 6, the processes of coating, exposing, and developing a photoresist layer may be performed to form a photoresist pattern on the layered structure ML with the first stair S1 in a manner similar to that in FIGS. 4A and 4B, and then, the multi-layer etching process may be performed on a portion of the layered structure ML exposed through the first recessed region RR1. Thus, a second recessed region RR2 may be formed.

Next, the trimming process and the single-layer etching process described with reference to FIG. 5 may be repeated. As a result, a second trimming mask pattern PMT2 may be formed, and then, a single-layer etching process using the second trimming mask pattern PMT2 may be repeated to form a second stair S2 and a second dummy stair DS2 in the connection region CNR and the scribe line region SCL, respectively. Since the second recessed region RR2 is formed, second dummy sacrificial patterns DP2 may be formed below the first dummy sacrificial patterns DP1 in the scribe line region SCL. The second dummy sacrificial patterns DP2 may define the second dummy stair DS2. The second stair S2 may be located at a level lower than the first stair S1 and may horizontally protrude toward the scribe line region SCL, compared with the first stair S1.

After the formation of the second stair S2 and the second dummy stair DS2, the second trimming mask pattern PMT2 may be removed through an ashing process and/or a strip process.

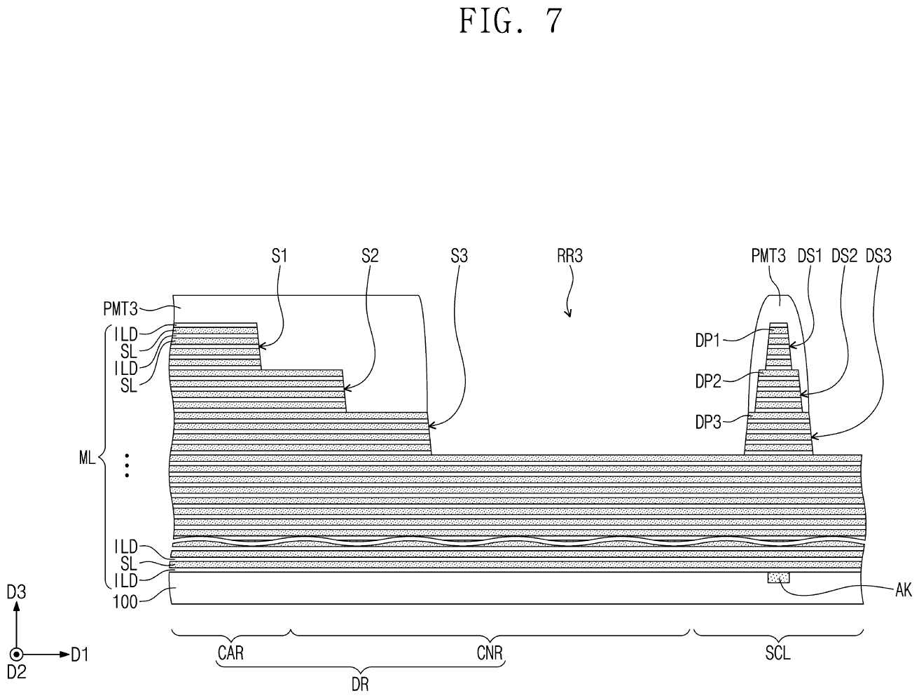

Referring to FIG. 7, as described with reference to FIG. 6, processes of coating, exposing, and developing a photoresist layer may be performed to form a photoresist pattern again on the layered structure ML with the first and second stairs S1 and S2, and the multi-layer etching process may be performed on a portion of the layered structure ML exposed through the second recessed region RR2. Thus, a third recessed region RR3 may be formed.

Next, the trimming process and the single-layer etching process described with reference to FIG. 5 may be repeated. As a result, a third trimming mask pattern PMT3 may be formed, and then, a single-layer etching process using the third trimming mask pattern PMT3 may be repeated to form a third stair S3 and a third dummy stair DS3 in the connection region CNR and the scribe line region SCL, respectively. In an embodiment, the third recessed region RR3 may be formed to define third dummy sacrificial patterns DP3 below the second dummy sacrificial patterns DP2 in the scribe line region SCL. The third dummy sacrificial patterns DP3 may define the third dummy stair DS3. The third stair S3 may be located at a level lower than the second stair S2 and may horizontally protrude toward the scribe line region SCL, relative to the second stair S2.

After the formation of the third stair S3 and the third dummy stair DS3, the third trimming mask pattern PMT3 may be removed through an ashing process and/or a strip process.

In an embodiment, as the multi-layer etching process and the single-layer etching process are repeated, depths and widths of the first, second, and third recessed regions RR1, RR2, and RR3, which are formed by etching a portion of the layered structure ML, may be decreased.

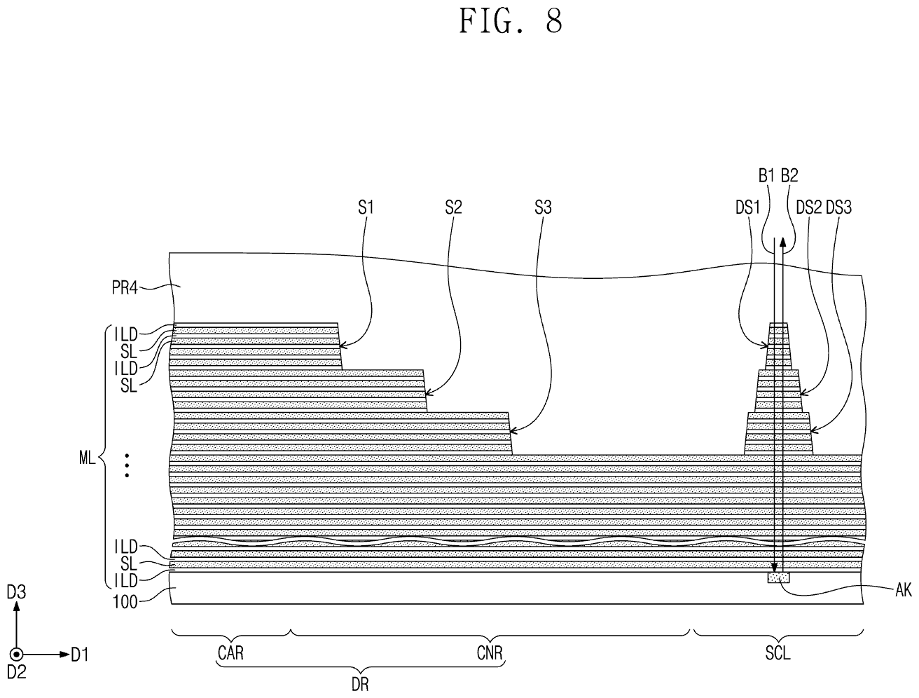

Referring to FIG. 8, a fourth photoresist layer PR4 may be formed on the layered structure ML with the first, second, and third stairs S1, S2, and S3.

The fourth photoresist layer PR4 may be deposited on the entire top surface of the substrate 100 through a spin coating process. The fourth photoresist layer PR4 may fill the first, second, and third recessed regions RR1, RR2, and RR3.

In an embodiment, since a portion of the layered structure ML remains in the scribe line region SCL that has the same vertical thickness as does the layered structure ML in the cell array region CAR, the flatness of the top surface of the fourth photoresist layer PR4 may be improved.

A pre-exposure measurement may be performed in an alignment system (not shown) to align the photomask, after the formation of the fourth photoresist layer PR4 as described above.

The pre-exposure measurement may include identifying the positions of the alignment keys AK formed in the substrate 100. In detail, the alignment system (not shown) may be configured to send an optical signal B1, which can pass through the fourth photoresist layer PR4 and the layered structure ML, to the alignment key AK and to sense an optical signal B2 reflected from the alignment key AK. In the alignment system, the optical properties (e.g., intensity, diffraction and/or interference patterns, and wavelength) of the reflected optical signal B2 may be used to find whether the substrate 100 is normally aligned.

When the top surface of the portion of the fourth photoresist layer PR4 above the alignment key AK has a significant inclination angle (slope) relative to the top surface of the substrate 100, the optical signal B2 that is reflected from the alignment key AK may be diffracted. This may reduce the accuracy with which the position of the alignment key AK can be determined. By forming the dummy sacrificial patterns DP1, DP2, and DP3 and the dummy stairs DS1, DS2, and DS3 in the scribe line region SCL, it may be possible to reduce a resulting slope of the top surface of the fourth photoresist layer PR4 over the alignment key AK. Accordingly, it may be possible to reduce the diffraction of the optical signal B2 reflected from the alignment key AK, and thus improve the accuracy with which the position of the alignment key AK is determined and accuracy of photomask alignment conducted with reference to the alignment key AK.

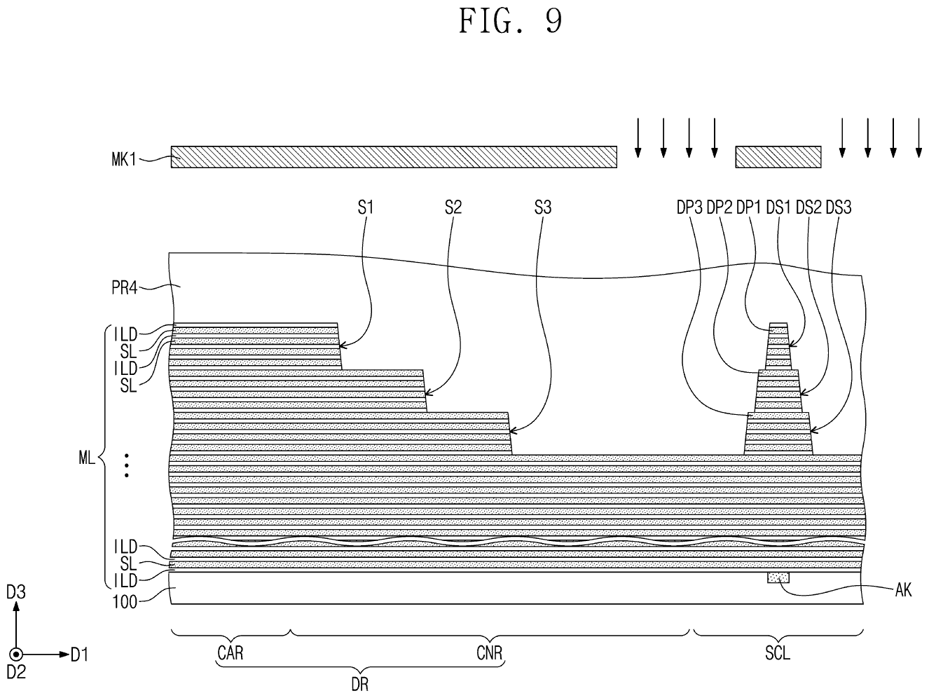

Following formation of the fourth photoresist layer PR4, referring to FIG. 9, an exposing process may be performed on the fourth photoresist layer PR4.

The exposing process on the fourth photoresist layer PR4 may be performed by aligning a photomask (e.g., a reticle) MK1 based on the determined position of the alignment key AK and then irradiating an electron beam or light onto the fourth photoresist layer PR4 through the photomask MK1.

Patterns that are formed in the photomask MK1 may be larger than patterns that are actually formed on the substrate 100, and the patterns that are formed in the photomask MK1 may be copied onto the fourth photoresist layer PR4 in a scaled-down manner.

In an embodiment, one of KrF, ArF, and extreme ultraviolet (EUV) beams may be used as a light source for the exposing process.

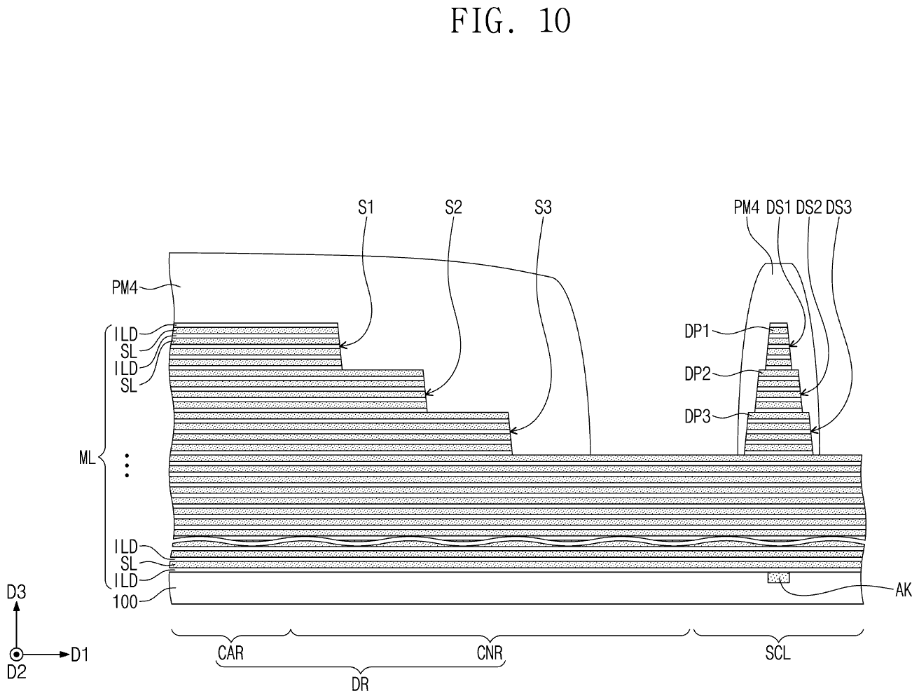

Referring to FIG. 10, following the exposing process of FIG. 9, a developing process may be performed on the fourth photoresist layer PR4 to form a fourth mask pattern PM4. As a result of the developing process, a portion of the fourth photoresist layer PR4 exposed during the exposing process of FIG. 9 may be removed. In an embodiment, an unexposed portion of the fourth photoresist layer PR4 may be removed, depending on the type of the fourth photoresist layer PR4. In an embodiment, a cleaning process using an de-ionized water may be further performed to remove a contamination material (e.g., particles) after the developing process.

The fourth mask pattern PM4 may cover the first, second, and third stairs S1, S2, and S3 and the first, second, and third dummy stairs DS1, DS2, and DS3 and may expose a portion of the layered structure ML in the third recessed region RR3.

A hard bake process may be performed after the exposing and developing processes. By virtue of the hard bake process, it may be possible to harden the photoresist pattern, to improve the etch-resistance of the photoresist pattern, and to increase an adhesion strength of the photoresist pattern to the substrate 100 (or an underlying layer). The hard bake process may be performed at a relatively high temperature, compared to the soft bake process.

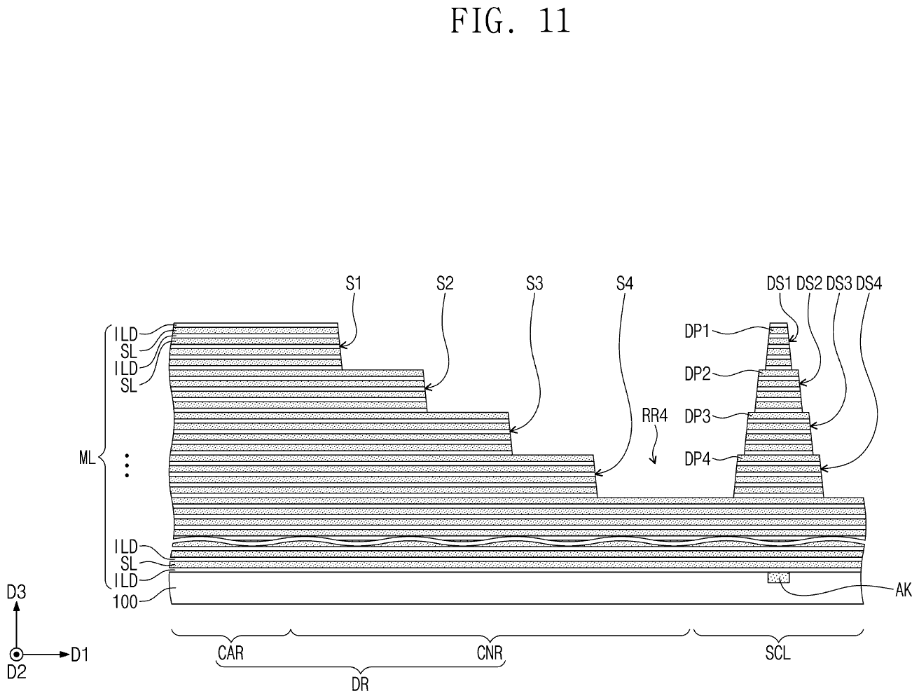

Referring to FIG. 11, the multi-layer etching process may be performed on a portion of the layered structure ML, which is exposed through the third recessed region RR3, using the fourth mask pattern PM4 as an etch mask. Accordingly, a fourth recessed region RR4 may be formed.

Next, the trimming process and the single-layer etching process described with reference to FIG. 5 may be repeated. Accordingly, a fourth trimming mask pattern (not shown) may be formed, and then, a single-layer etching process using the fourth trimming mask pattern may be repeated to form a fourth stair S4 and a fourth dummy stair DS4 in the connection region CNR and the scribe line region SCL, respectively. Since the fourth recessed region RR4 is formed, fourth dummy sacrificial patterns DP4 may be formed below the third dummy sacrificial patterns DP3 in the scribe line region SCL. The fourth dummy sacrificial patterns DP4 may define the fourth dummy stair DS4. The fourth stair S4 may be located at a level lower than the third stair S3 and may horizontally protrude toward the scribe line region SCL relative to the third stair S3. The fourth stair S4 and the fourth dummy stair DS4 may have substantially the same inclination angle.

After the formation of the fourth stair S4 and the fourth dummy stair DS4, the fourth trimming photoresist pattern may be removed through an ashing process and/or a strip process.

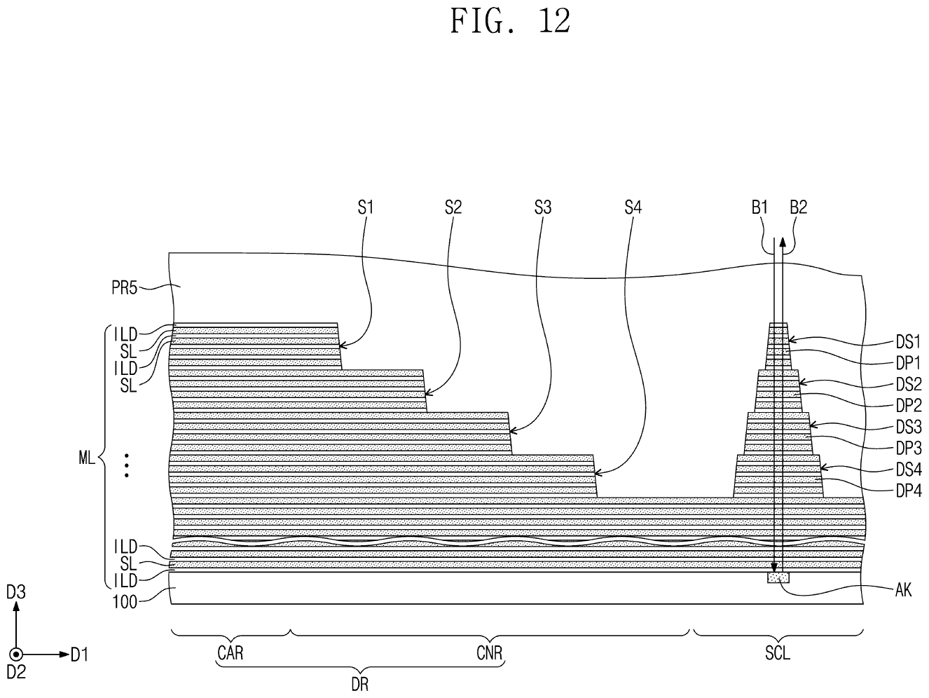

Referring to FIG. 12, a fifth photoresist layer PR5 may be formed by performing the spin coating process, as previously described with reference to FIG. 8. The fifth photoresist layer PR5 may be formed to fill the first, second, third, and fourth recessed regions RR1, RR2, RR3, and RR4.

Next, a pre-exposure measurement using the alignment keys AK may be performed, as described with reference to FIG. 8. Here, the pre-exposure measurement may include irradiating the alignment key AK with the optical signal B1, which may pass through the fourth photoresist layer PR4 and the layered structure ML, and sensing the optical signal B2 reflected from the alignment key AK. Due to the formation of the dummy sacrificial patterns DP1, DP2, DP3, and DP4 and the dummy stairs DS1, DS2, DS3, and DS4 in the scribe line region SCL, it may be possible to reduce a slope of the top surface of the fifth photoresist layer PR5 in the scribe line region SCL. Accordingly, it may be possible to reduce the diffraction of the optical signal B2 reflected from the alignment key AK.

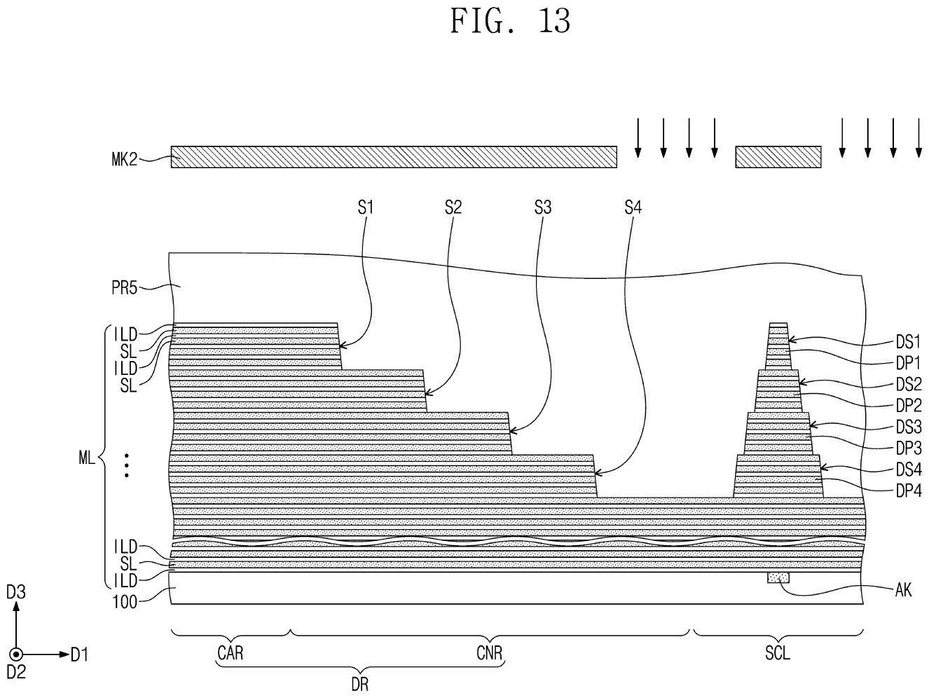

Referring to FIG. 13, an exposing process may be performed on the fifth photoresist layer PR5. The exposing process on the fifth photoresist layer PR5 may be performed by aligning a photomask MK2 (e.g., a reticle) based on the determined position of the alignment key AK and then irradiating an electron beam or light onto the fifth photoresist layer PR5 through the photomask MK2.

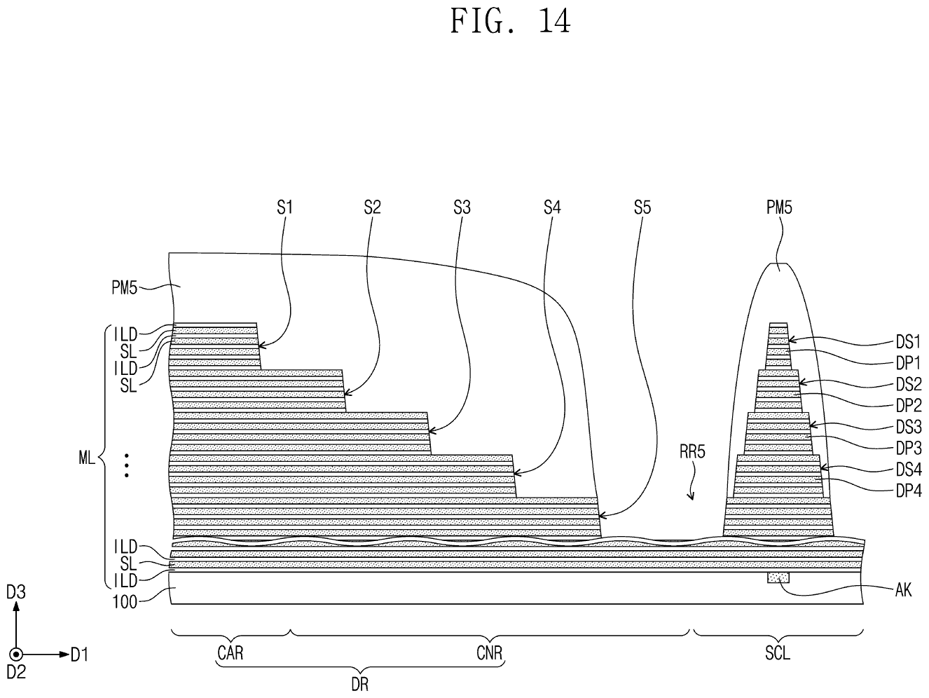

Referring to FIG. 14, following the exposing process of FIG. 13, developing process may be performed on the fifth photoresist layer PR5 to form a fifth mask pattern PM5. A multi-layer etching process using the fifth mask pattern PM5 as an etch mask may then be performed on a portion of the layered structure ML exposed through the fourth recessed region RR4. Accordingly, a fifth recessed region RR5 may be formed.

Next, the trimming process and the single-layer etching process described with reference to FIG. 5 may be repeated. Accordingly, a fifth trimming mask pattern (not shown) may be formed, and then, a single-layer etching process using the fifth trimming mask pattern may be repeated to form a fifth stair S5 in the connection region CNR and a fifth dummy stair DS5 in the scribe line region SCL. Since the fifth recessed region RR5 is formed, fifth dummy sacrificial patterns DP5 may be formed below the fourth dummy sacrificial patterns DP4 in the scribe line region SCL. The fifth dummy sacrificial patterns DP5 may define the fifth dummy stair DS5. The fifth stair S5 may be located at a level lower than the fourth stair S4 and may horizontally protrude toward the scribe line region SCL relative to the fourth stair S4. The fifth stair S5 and the fifth dummy stair DS5 may have substantially the same inclination angle.

After the formation of the fifth stair S5 and the fifth dummy stair DS5, the fifth trimming photoresist pattern may be removed through an ashing process and/or a strip process.

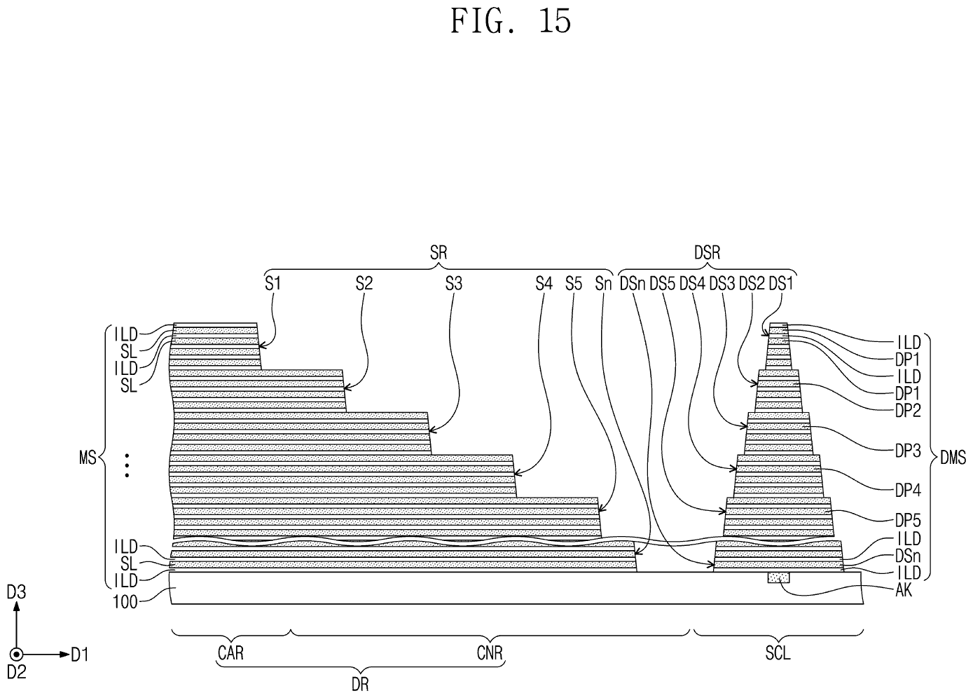

Referring to FIG. 15, the processes of forming the mask pattern again and performing the multi-layer etching process, the trimming process, and the single-layer etching process on the layered structure may be repeated, in a similar way to those described with reference to FIGS. 12, 13, and 14.

Thus, a mold structure MS having the first staircase structure SR may be formed on the connection region CNR, and a dummy mold structure DMS having the second staircase structure DSR may be formed on the scribe line region SCL. The dummy mold structure DMS may be separated and spaced apart from the mold structure MS, and may overlap with the alignment key AK. In the dummy mold structure DMS, the uppermost first dummy sacrificial pattern DPI may have a first width that is the smallest width of the dummy mold structure DMS in the first direction D1, and the first width may be larger than the largest width of the alignment key AK in the first direction D1.

In the mold structure MS, the first staircase structure SR may include the first to n-th stairs S1 to Sn. In the dummy mold structure DMS, the second staircase structure DSR may include the first to n-th dummy stairs DS1 to DSn.

The inclination angle of each of the first to n-th stairs S1 to Sn may be substantially equal to the inclination angle of each of the first to n-th dummy stairs DS1 to DSn.

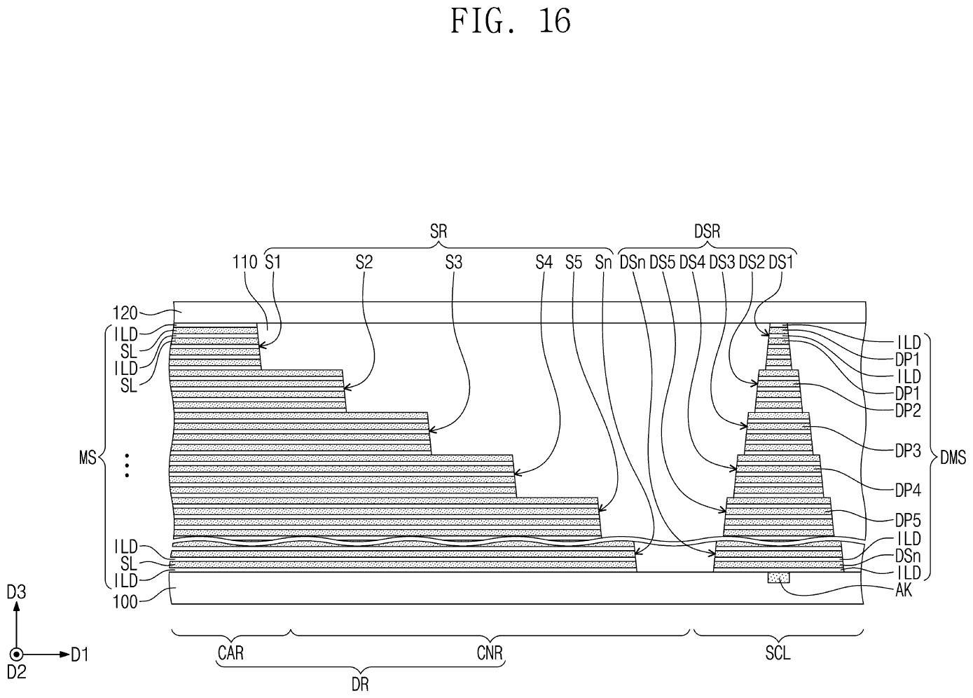

Referring to FIG. 16, the insulating gapfill layer 110 may be formed to fill a space between the mold structure MS and the dummy mold structure DMS. A top surface of the insulating gapfill layer 110 may be substantially coplanar with the top surfaces of the mold structure MS and the dummy mold structure DMS.

The first planarization insulating layer 120 may be formed to cover the top surfaces of the insulating gapfill layer 110, the mold structure MS, and the dummy mold structure DMS.

Next, in the chip region DR, a replacement process may be performed to replace the sacrificial layers SL of the mold structure MS with the conductive patterns GE.

The replacement process may include, before or after forming the peripheral contact plugs PPLG and/or the separation structures SS in one embodiment, removing the sacrificial layers SL through an isotropic etching process, in which an etch recipe is chosen to have an etch selectivity with respect to the interlayer insulating layers ILD, and filling empty regions between the interlayer insulating layers ILD, which are formed by removing the sacrificial layers SL, with a conductive material. Accordingly, the stack ST, in which the interlayer insulating layers ILD and the conductive patterns GE are alternately stacked, may be formed on the substrate 100. In one embodiment, during the replacement process, the sacrificial layers SL of the dummy mold structure DMS are not replaced.

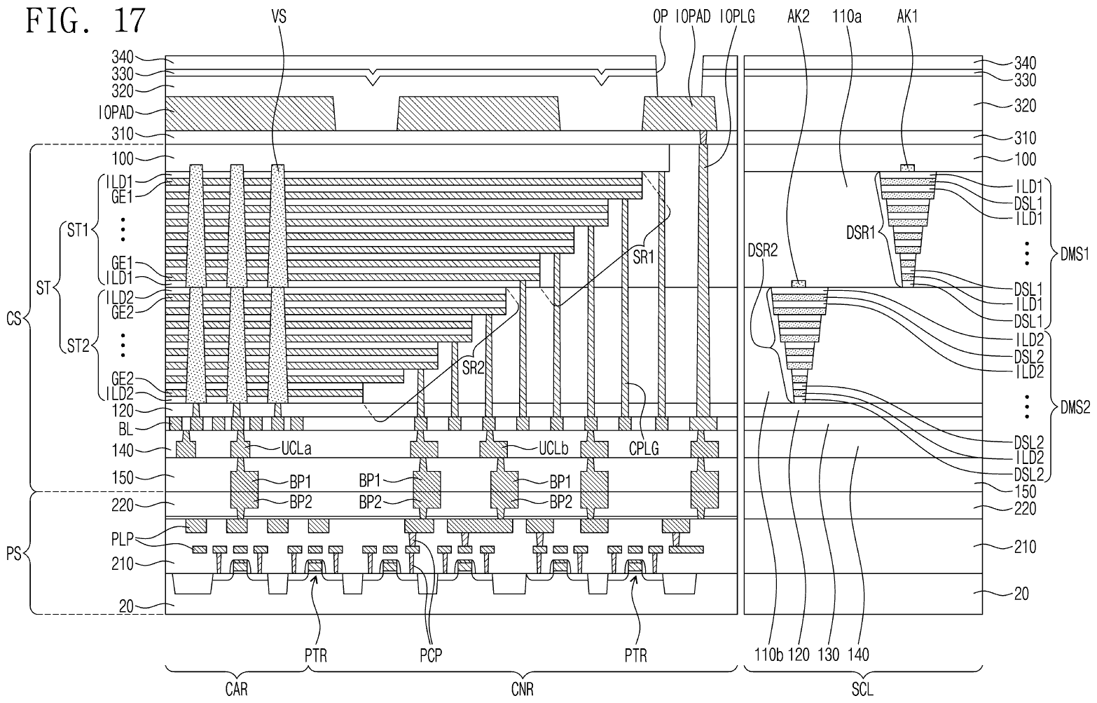

FIG. 17 is a sectional view illustrating a semiconductor device according to an embodiment of the inventive concept.

Referring to FIG. 17, a semiconductor device according to an embodiment of the inventive concept may have a chip-to-chip (C2C) structure. For the C2C structure, an upper chip including a cell array structure CS may be fabricated on a first wafer, a lower chip including a peripheral circuit structure PS may be fabricated on a second wafer different from the first wafer, and the upper chip and the lower chip may be connected to each other through a bonding method. The bonding method may involve electrically connecting a bonding metal, which is formed in an uppermost metal layer of the upper chip, to a bonding metal that may be formed in an uppermost metal layer of the lower chip. In an example, the bonding metal is formed of copper (Cu), and the bonding method may be a Cu-to-Cu bonding method. In other examples, aluminum (Al) or tungsten (W) may be used as the bonding metal.

The cell array structure CS may include a memory cell array including memory cells, which are three-dimensionally arranged on the substrate 100. The memory cell array may be electrically connected to first bonding pads BP1.

The cell array structure CS may include the cell array region CAR, the connection region CNR, and the scribe line region SCL.

The cell array structure CS may include a stack ST, vertical structures VS, bit lines BL, cell contact plugs CPLG, and input/output contact plugs IOPLG.

The stack ST may include a first stack ST1, in which first interlayer insulating layers ILD1 and first conductive patterns GE1 are alternatingly stacked, and a second stack ST2, in which second interlayer insulating layers ILD2 and second conductive patterns GE2 are alternatingly stacked.

The first stack ST1 may have a first staircase structure SR1 in the connection region CNR, and the second stack ST2 may have a second staircase structure SR2 in the connection region CNR. The first and second staircase structures SR1 and SR2 may be configured to have substantially the same features as the first staircase structure SR of the stack ST described with reference to FIGS. 3 and 4.

Each of the first and second conductive patterns GE1 and GE2 may include a pad portion in the connection region CNR, and the cell contact plugs CPLG may be coupled to the pad portions of the first and second conductive patterns GE1 and GE2.

In an embodiment, the second stack ST2 may be disposed between the first stack ST1 and the peripheral circuit structure PS. More specifically, the second stack ST2 may be provided on a bottom surface of the bottommost one of the first interlayer insulating layers ILD1 of the first stack ST1. The topmost one of the second interlayer insulating layers ILD2 of the second stack ST2 may be in contact with the bottommost one of the first interlayer insulating layers ILD1 of the first stack ST1, but the inventive concept is not limited to this example; for example, a single insulating layer may be provided between the topmost one of the second conductive patterns GE2 of the second stack ST2 and the first conductive patterns GE1 of the first stack ST1.

Insulating gapfill layers 110a and 110b may cover respective end portions (i.e., pad portions) of the stack ST having the staircase structure. The insulating gapfill layers 110a and 110b may have substantially flat top surfaces. The insulating gapfill layers 110a and 110b may include respective single insulating layers or respective pluralities of insulating layers. In an embodiment, insulating gapfill layer 110a may cover the first staircase structure SR1 of the first stack ST1 and insulating gapfill layer 110b may cover the second staircase structure SR2 of the second stack ST2.

The vertical structures VS may be provided in the cell array region CAR and may vertically penetrate the stack ST. The vertical structures VS may be arranged in a specific direction or in a zigzag shape, when viewed in a plan view. Vertical structures VS may also be provided in the connection region CNR and may penetrate the end portions (i.e., pad portions) of the first and second conductive patterns GE1 and GE2.

Each of the vertical structures VS in the cell array region CAR may be provided in a vertical channel hole penetrating the stack ST. In an embodiment, each such vertical channel hole may include a first vertical channel hole penetrating the first stack ST1 and a second vertical channel hole penetrating the second stack ST2 and connecting with the first vertical channel hole.

According to an embodiment of the inventive concept, in the scribe line region SCL, a first alignment key AK1 may be disposed in the substrate 100, and a second alignment key AK2 may be disposed in the insulating gapfill layer 110. The second alignment key AK2 may be non-overlapped with the first alignment key AK1.

In an embodiment, first and second dummy mold structures DMS1 and DMS2 may be disposed in the scribe line region SCL, and the second dummy mold structure DMS2 may be disposed between the first dummy mold structure DMS1 and the peripheral circuit structure PS. The first and second dummy mold structures DMS1 and DMS2 may include first and second dummy sacrificial layers DSL1 and DSL2, which are located at same respective vertical levels as the first and second conductive patterns GE1 and GE2.

The first dummy mold structure DMS1 may be disposed at the same vertical level as the first stack ST1 and may have substantially the same height. The first dummy mold structure DMS1 may be overlapped with the first alignment key AK1 and may have a first dummy staircase structure DSR1. The first dummy staircase structure DSR1 and the first staircase structure SR1 may be formed at the same time and may have substantially the same staircase features. The first dummy staircase structure DSR1 may be formed to have substantially the same features as the dummy staircase structure DSR previously described with reference to FIGS. 3 and 4.

The second dummy mold structure DMS2 may be disposed at the same vertical level as the second stack ST2 and may have substantially the same height. The second dummy mold structure DMS2 may be overlapped with the second alignment key AK2 but not with the first alignment key AK2 or the first dummy mold structure DMS1, and may have a second dummy staircase structure DSR2. The second dummy staircase structure DSR2 and the second staircase structure SR2 may be formed at the same time and may have substantially the same staircase features. The second dummy staircase structure DSR2 may be formed to have substantially the same features as the dummy staircase structure DSR previously described with reference to FIGS. 3 and 4.

The first planarization insulating layer 120 may cover the vertical structures VS and the insulating gapfill layer 110b.

The bit lines BL may be disposed on the first planarization insulating layer 120, in the cell array region CAR. The bit lines BL may extend to cross the stack ST. The bit lines BL may be electrically connected to the vertical structures VS through bit line contact plugs.

Second, third, and fourth planarization insulating layers 130, 140, and 150 may be disposed on the first planarization insulating layer 120. Upper conductive lines UCLa and UCLb may be disposed in the third planarization insulating layer 140. The upper conductive lines UCLa may be electrically connected to the bit lines BL in the cell array region CAR. The upper conductive lines UCLb may be electrically connected to conductive lines and the cell contact plugs CPLG in the connection region CNR.

The first bonding pads BP1 may be disposed in the fourth planarization insulating layer 150, which is the uppermost one of the interlayer insulating layers. The first bonding pads BP1 may be electrically connected to the upper conductive lines UCLa and UCLb. The first bonding pads BP1 may be formed of or include copper.

A surface insulating layer 310 may cover a rear surface of the substrate 100. Input/output pads IOPAD may be disposed on the surface insulating layer 310.

The input/output contact plugs IOPLG may penetrate the insulating gapfill layers 110a and 110b and may be electrically connected to the input/output pad IOPAD. The input/output pads IOPAD may be electrically connected to the peripheral circuit structure PS through the input/output contact plugs IOPLG.

An upper insulating layer 320 may be disposed on the surface insulating layer 310, and the upper insulating layer 320 may cover the input/output pads IOPAD.

A capping insulating layer 330 and a passivation layer 340 may be sequentially formed on the upper insulating layer 320. The capping insulating layer 330 may be, for example, a silicon nitride layer or a silicon oxynitride layer. The passivation layer 340 may be formed of or include polyimide-based materials (e.g., photo sensitive polyimide (PSPI)).

The capping insulating layer 330 and the passivation layer 340 may be formed to have a pad opening OP exposing a portion of the input/output pad IOPAD.

The peripheral circuit structure PS may be formed on a peripheral circuit substrate 20 and may include peripheral circuits PTR controlling the memory cell array and peripheral interlayer insulating layers 210 and 220 covering the peripheral circuits PTR.

The peripheral circuit substrate 20 may be, for example, a single crystalline silicon substrate, and the peripheral circuits PTR may be integrated on a top surface of the peripheral circuit substrate 20.

The peripheral circuits PTR may include row and column decoders, a page buffer, a control circuit, and so forth. In more detail, the peripheral circuits PTR may include NMOS and PMOS transistors. Peripheral circuit interconnection lines PLP may be electrically connected to the peripheral circuits PTR through the peripheral contact plugs PCP.

The peripheral interlayer insulating layers 210 and 220 may be provided on the top surface of the peripheral circuit substrate 20. The peripheral interlayer insulating layers 210 and 220 may be provided on the peripheral circuit substrate 20 to cover the peripheral circuits PTR, the peripheral contact plugs PCP, and the peripheral circuit interconnection lines PLP. The peripheral contact plugs PCP and the peripheral circuit interconnection lines PLP may be electrically connected to the peripheral circuits PTR. The peripheral interlayer insulating layers 210 and 220 may include a silicon oxide layer, a silicon nitride layer, a silicon oxynitride layer, and/or a low-k dielectric layer.

Second bonding pads BP2 may be provided in the uppermost layer (i.e., 220) of the peripheral interlayer insulating layers to connect with the first bonding pads BP1. The second bonding pads BP2 may be electrically connected to the peripheral circuits PTR through the peripheral circuit interconnection lines PLP and the peripheral contact plugs PCP.

The second bonding pads BP2 may be electrically and physically connected to the first bonding pads BP1 by a bonding method. The second bonding pads BP2 may be in contact with the first bonding pads BP1.

The second bonding pads BP2 may include a same metallic material as the first bonding pads BP1. The second bonding pads BP2 may be substantially the same as the first bonding pads BP1 in terms of shape, width, or area.

In later steps in the manufacturing process, external connection terminals, such as solder bumps or balls, may be connected to input/output pads IOPAD, and a dicing process may be performed to singulate the semiconductor device from a wafer and to form a semiconductor chip formed on a die. In the dicing process, one or more of the first dummy staircase structure DSR1 and second dummy staircase structure DSR2, or a portion of one or more of the first dummy staircase structure DSR1 and second dummy staircase structure DSR2 may be removed, and another portion may remain on the separated semiconductor device. A remaining portion of a dummy staircase structure may still be referred to as a dummy staircase structure, or may be described as a scribe lane staircase structure, or an edge region isolated staircase structure.

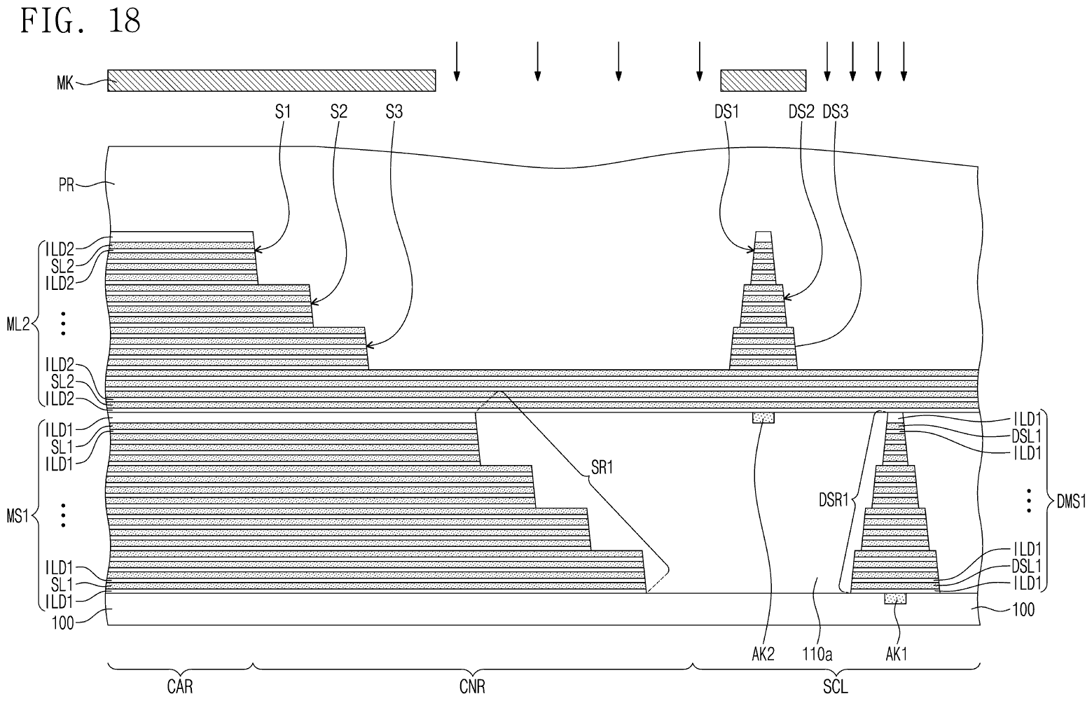

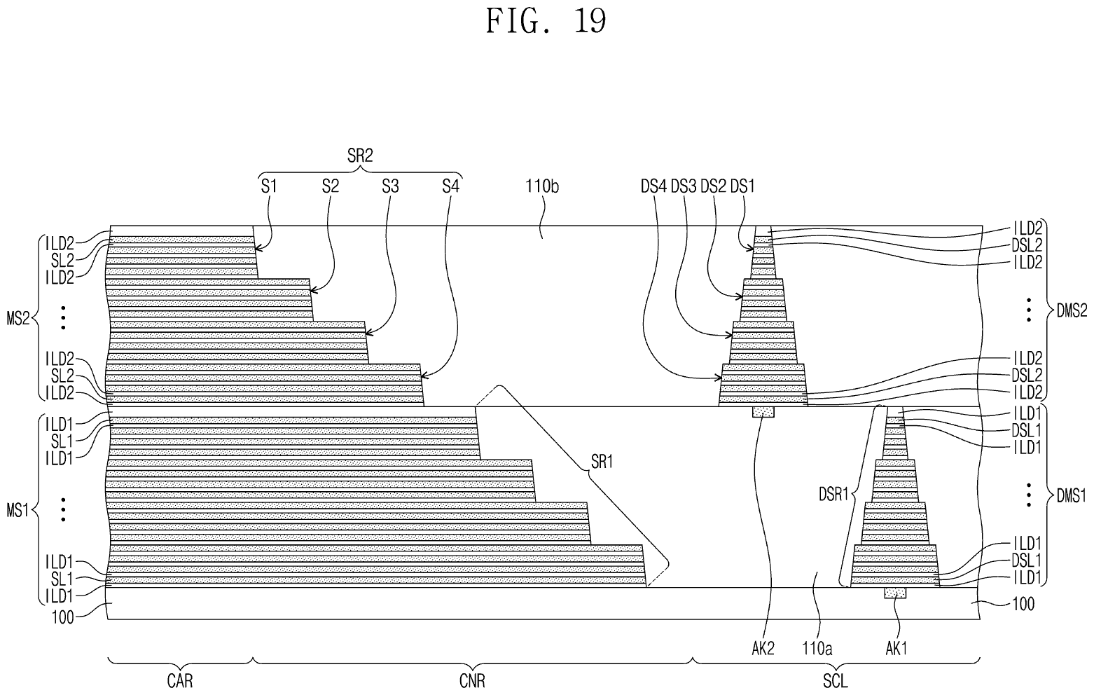

FIGS. 18 and 19 are sectional views illustrating a method of fabricating a semiconductor device, according to an embodiment of the inventive concept.

Referring to FIG. 18, the substrate 100 may include the cell array region CAR, the connection region CNR, and the scribe line region SCL.

The substrate 100 includes a first alignment key AK1, which are provided in the scribe line region SCL and are used for a photolithography process. Although not shown in the drawings, the substrate 100 may include the peripheral circuit structure described above, and the first alignment key AK1 may be formed simultaneously with the peripheral interconnection lines in the peripheral circuit structure.

A first mold structure MS1 having the first staircase structure SR1 and a first dummy mold structure DMS1 having the first dummy staircase structure DSR1 may be formed on the connection region CNR of the substrate 100.

As previously described with reference to FIGS. 4A, 4B, and 5 to 15, the first mold structure MS1 and the first dummy mold structure DMS1 may be formed by forming a layered structure on the substrate 100 and performing a patterning process using the first alignment key AK1.

In the first mold structure MS1, the first staircase structure SR1 may include first to n-th stairs S1 to Sn (as shown in FIG. 16). In the first dummy mold structure DMS1, the first dummy staircase structure DSR1 may include first to n-th dummy stairs DS1 to DSn (as also shown in FIG. 16).

The inclination angle of each of the first to n-th stairs S1 to Sn with respect to a line perpendicular to the top surface of the substrate 100 may be substantially equal to the inclination angle of each of the first to n-th dummy stairs DS1 to DSn.

The first insulating gapfill layer 110a may be formed to fill a space between the first mold structure MS1 and the first dummy mold structure DMS1. A top surface of the first insulating gapfill layer 110a may be substantially coplanar with the top surfaces of the first mold structure MS1 and the first dummy mold structure DMS1.

A second alignment key AK2 may be formed in the first insulating gapfill layer 110a, in the scribe line region SCL. In one embodiment, the second alignment key AK2 does not overlap the first alignment key AK1 in a plan view.

After the formation of the second alignment key AK2, a second layered structure ML2 may be formed on the top surfaces of the first mold structure MS1, the first insulating gapfill layer 110a, and the first dummy mold structure DMS1. The second layered structure ML2 may include the second interlayer insulating layers ILD2 and the second sacrificial layers SL2, which may be vertically and alternatingly stacked on the top surfaces of the first mold structure MS1, the first insulating gapfill layer 110a, and the first dummy mold structure DMS1.

As previously described with reference to FIGS. 4A, 4B, and 5 to 15, a patterning process using the second alignment key AK2 may be repeated on the second layered structure ML2. In the patterning process on the second layered structure ML2, an exposing process may be performed using a photomask MK, and in an embodiment, a pre-exposure measurement using the second alignment key AK2 may be performed in an alignment system (not shown), before the exposing process.

Referring to FIG. 19, by repeating the patterning process on the second layered structure ML2, first to fourth stairs S1 to S4 and first to fourth dummy stairs DS1 to DS4 may be formed in the second layered structure ML2, to create a second mold structure MS2 in the connection region CNR and a second dummy mold structure DMS2 in the scribe line region SCL.

The second mold structure MS2 may have a second staircase structure SR2 that includes the first to fourth stairs S1 to S4, and the second dummy mold structure DMS2 may have a second dummy staircase structure DSR2 that includes the first to fourth dummy stairs DS1 to DS4.

A second insulating gapfill layer 110b may be formed to cover the second staircase structure SR2 and the second dummy staircase structure DSR2.

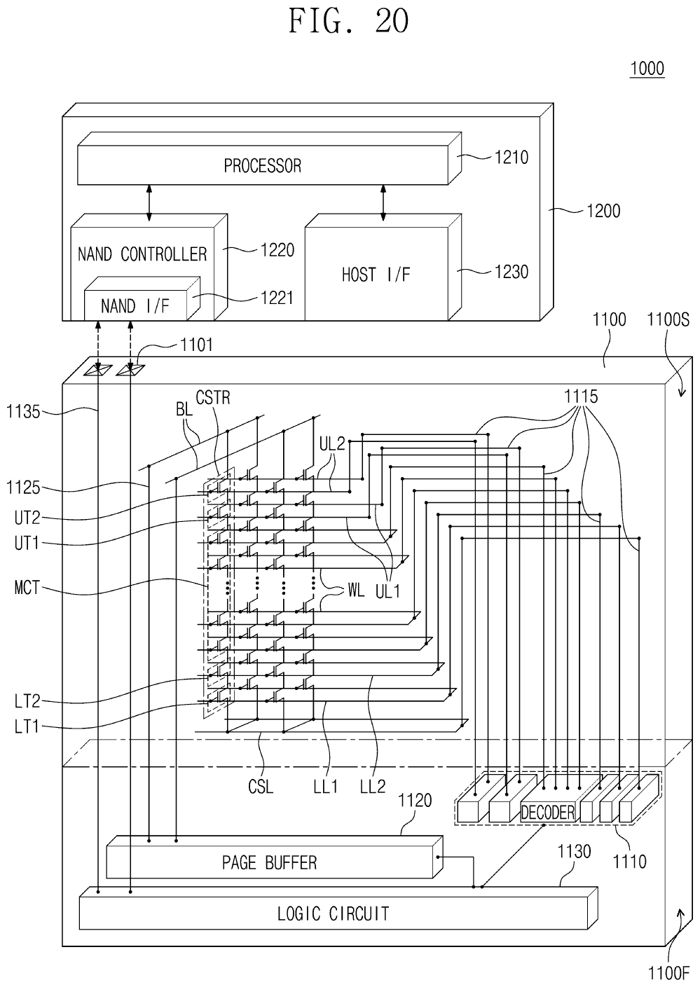

FIG. 20 is a diagram schematically illustrating an electronic system including a semiconductor device according to an embodiment of the inventive concept.

Referring to FIG. 20, an electronic system 1000 according to an embodiment of the inventive concept may include a semiconductor device 1100 and a controller 1200, which is electrically connected to the semiconductor device 1100. The electronic system 1000 may be a storage device, which includes one or more semiconductor devices 1100, or an electronic device including the storage device. For example, the electronic system 1000 may be a solid state drive (SSD) device, a universal serial bus (USB), a computing system, a medical system, or a communication system, in which at least one semiconductor device 1100 is provided.

The semiconductor device 1100 may be a nonvolatile memory device (e.g., a NAND FLASH memory device). The semiconductor device 1100 may include a first structure 1100F and a second structure 1100S on the first structure 1100F. In an embodiment, the first structure 1100F may be disposed near the second structure 1100S.

The first structure 1100F may be a peripheral circuit structure, which may include a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be variously changed, according to embodiments.

In an embodiment, the upper transistors UT1 and UT2 may include at least one string selection transistor, and the lower transistors LT1 and LT2 may include at least one ground selection transistor. The gate lower lines LL1 and LL2 may be used as gate electrodes of the lower transistors LT1 and LT2, respectively. The word lines WL may be used as gate electrodes of the memory cell transistors MCT, and the gate upper lines UL1 and UL2 may be used as gate electrodes of the upper transistors UT1 and UT2, respectively.

In an embodiment, the lower transistors LT1 and LT2 may include a lower erase control transistor LT1 and a ground selection transistor LT2, which are connected in series. The upper transistors UT1 and UT2 may include a string selection transistor UT1 and an upper erase control transistor UT2, which are connected in series. At least one of the lower and upper erase control transistors LT1 and UT1 may be used to perform an erase operation of erasing data in the memory cell transistors MCT using a gate-induced drain leakage (GIDL) phenomenon.

The common source line CSL, the first and second gate lower lines LL1 and LL2, the word lines WL, and the first and second gate upper lines UL1 and UL2 may be electrically connected to the decoder circuit 1110 through first connection lines 1115, which extend from the first structure 1100F to the second structure 1100S. The bit lines BL may be electrically connected to the page buffer 1120 through second connection lines 1125, which extend from the first structure 1100F to the second structure 1100S.

In the first structure 1100F, the decoder circuit 1110 and the page buffer 1120 may be configured to perform a control operation on at least one transistor that is selected from the memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection line 1135, which is provided in the first structure 1100F and extends into the second structure 1100S.

Although not shown, the first structure 1100F may include a voltage generator (not shown). The voltage generator may generate a program voltage, a read voltage, a pass voltage, a verification voltage, and so forth, which may be used to operate the memory cell strings CSTR. Here, the program voltage may be a relatively high voltage (e.g., 20V to 40V), compared with the read voltage, the pass voltage, and the verification voltage.

In an embodiment, the first structure 1100F may include high voltage transistors and low voltage transistors. The decoder circuit 1110 may include pass transistors connected to the word lines WL of the memory cell strings CSTR. The pass transistors may include high-voltage transistors which can stand a high voltage (e.g., a program voltage applied to the word lines WL during a programming operation). The page buffer 1120 may also include high-voltage transistors which can accommodate the high voltage.

The controller 1200 may include a processor 1210, a NAND controller 1220, and a host interface 1230. In an embodiment, the electronic system 1000 may include a plurality of semiconductor devices 1100, and in this case, the controller 1200 may control the semiconductor devices 1100.

The processor 1210 may control overall operations of the electronic system 1000 including the controller 1200. The processor 1210 may be operated based on a specific firmware and may control the NAND controller 1220 to access the semiconductor device 1100. The NAND controller 1220 may include a NAND interface 1221, which is used to communicate with the semiconductor device 1100. The NAND interface 1221 may be used to transmit and receive control commands for controlling the semiconductor device 1100 and data to be written in or read from the memory cell transistors MCT of the semiconductor device 1100. The host interface 1230 may be configured to allow for communication between the electronic system 1000 and an external host. When a control command is received from an external host through the host interface 1230, the processor 1210 may control the semiconductor device 1100 in response to the control command.

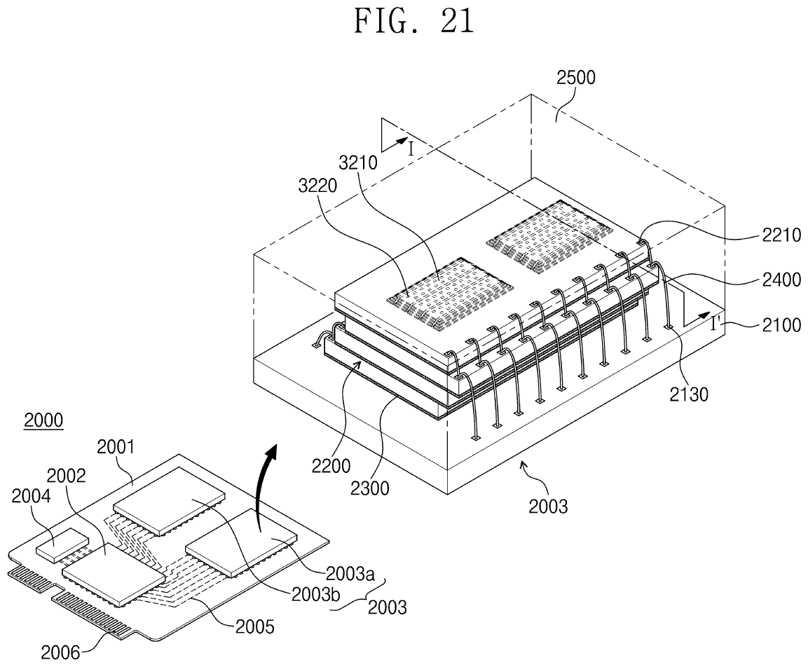

FIG. 21 is a perspective view schematically illustrating an electronic system including a semiconductor device according to an embodiment of the inventive concept.

Referring to FIG. 21, an electronic system 2000 according to an embodiment of the inventive concept may include a main substrate 2001 and a controller 2002, at least one semiconductor package 2003, and a DRAM 2004, which are mounted on the main substrate 2001. The semiconductor package 2003 and the DRAM 2004 may be connected to the controller 2002 through interconnection patterns 2005, which are formed in the main substrate 2001.

The main substrate 2001 may include a connector 2006, which includes a plurality of pins coupled to an external host. In the connector 2006, the number and arrangement of the pins may depend on a communication interface between the electronic system 2000 and the external host. In an embodiment, the electronic system 2000 may communicate with the external host in accordance with one or more interface standards, such as universal serial bus (USB), peripheral component interconnect express (PCI-Express), serial advanced technology attachment (SATA), universal flash storage (UFS) M-Phy, or the like. In an embodiment, the electronic system 2000 may be driven by power supplied from the external host through the connector 2006. The electronic system 2000 may further include a power management integrated circuit (PMIC) configured to separately supply an electric power from the external host to the controller 2002 and the semiconductor package 2003.

The controller 2002 may be configured to control writing and/or reading operations of the semiconductor package 2003 and to optimize an operation speed of the electronic system 2000.

The DRAM 2004 may be a buffer memory that is configured to relieve technical difficulties caused by a difference in speed between the semiconductor package 2003, which serves as a data storage device, and an external host. In an embodiment, the DRAM 2004 in the electronic system 2000 may serve as a cache memory and may be used as a storage space, which is used to temporarily store data during a control operation on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 respectively disposed on bottom surfaces of the semiconductor chips 2200, a connection structure 2400 electrically connecting the semiconductor chips 2200 to the package substrate 2100, and a molding layer 2500 disposed on the package substrate 2100 to cover the semiconductor chips 2200 and the connection structure 2400.

The package substrate 2100 may be a printed circuit board including upper pads 2130. Each of the semiconductor chips 2200 may include an input/output pad 2210. The input/output pad 2210 may correspond to the input/output pad 1101 of FIG. 20. Each of the semiconductor chips 2200 may include stacks 3210 and vertical structures 3220. Each of the semiconductor chips 2200 may include a semiconductor device, which will be described below, according to an embodiment of the inventive concept.

In an embodiment, the connection structure 2400 may include a bonding wire electrically connecting the input/output pad 2210 to the upper pads 2130. Thus, in each of the first and second semiconductor packages 2003a and 2003b, the semiconductor chips 2200 may be electrically connected to each other by bonding wires and may be electrically connected to the upper pads 2130 of the package substrate 2100. In an embodiment, the semiconductor chips 2200 in each of the first and second semiconductor packages 2003a and 2003b may be electrically connected to each other by a connection structure including through silicon vias (TSVs), not by the connection structure 2400 provided in the form of bonding wires.

In an embodiment, the controller 2002 and the semiconductor chips 2200 may be included in a single package. In an embodiment, the controller 2002 and the semiconductor chips 2200 may be mounted on a separate interposer substrate, which is prepared regardless of the main substrate 2001, and may be connected to each other through interconnection lines, which are provided in the interposer substrate.

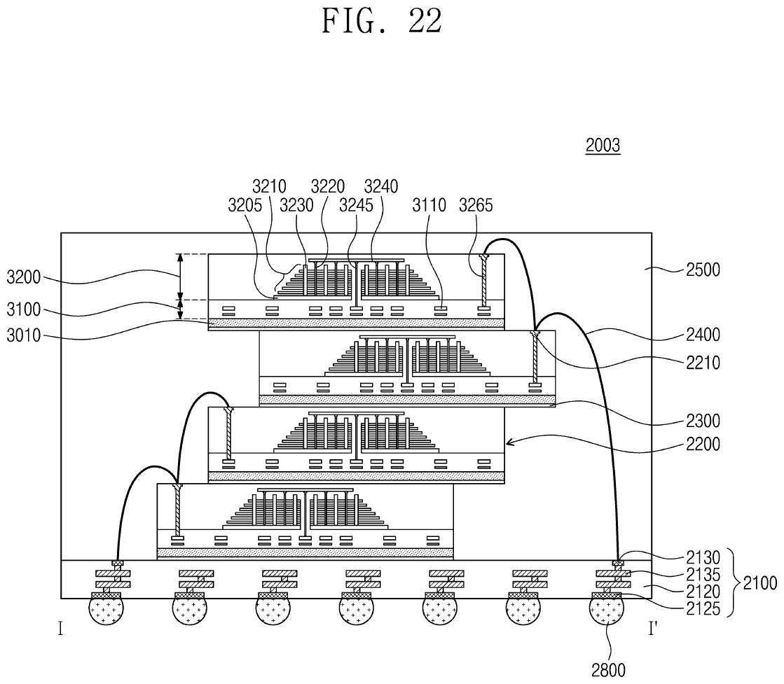

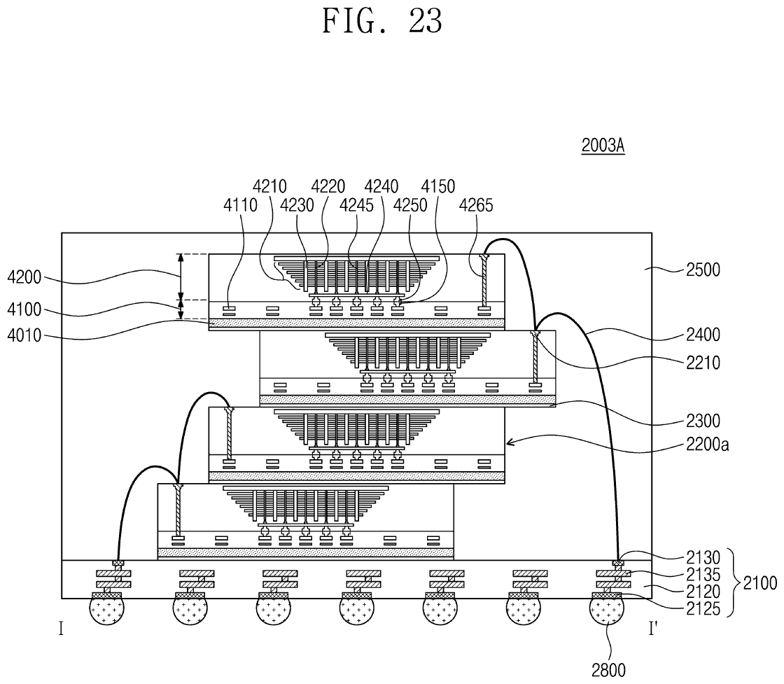

FIGS. 22 and 23 are sectional views schematically illustrating semiconductor packages according to an embodiment of the inventive concept. In detail, FIGS. 22 and 23 are sectional views, which are taken along a line I-I′ of FIG. 21 to illustrate two different examples of the semiconductor package of FIG. 21.

Referring to FIG. 22, in the semiconductor package 2003, the package substrate 2100 may be a printed circuit board. The package substrate 2100 may include a package substrate body portion 2120, the upper pads 2130 (e.g., of FIG. 21), which are disposed on a top surface of the package substrate body portion 2120, lower pads 2125, which are disposed on or exposed through a bottom surface of the package substrate body portion 2120, and internal lines 2135, which are provided in the package substrate body portion 2120 to electrically connect the upper pads 2130 to the lower pads 2125. The upper pads 2130 may be electrically connected to the connection structures 2400. The lower pads 2125 may be connected to the interconnection patterns 2005 of the main substrate 2001 of the electronic system 2000 through conductive connecting portions 2800, as shown in FIG. 21.

Each of the semiconductor chips 2200 may include a semiconductor substrate 3010 and first and second structures 3100 and 3200, which are sequentially stacked on the semiconductor substrate 3010. The first structure 3100 may include a peripheral circuit region, in which peripheral lines 3110 are provided. The second structure 3200 may include a source structure 3205, a stack 3210 on the source structure 3205, the vertical structures 3220 and separation structures penetrating the stack 3210, bit lines 3240 electrically connected to the vertical structures 3220, and cell contact plugs electrically connected to the word lines WL (e.g., of FIG. 20) of the stack 3210. Each of the first and second structures 3100 and 3200 and the semiconductor chips 2200 may further include separation structures to be described below.

Each of the semiconductor chips 2200 may include penetration lines 3245, which are electrically connected to the peripheral lines 3110 of the first structure 3100 and extend into the second structure 3200. The penetration lines 3245 may be disposed outside the stack 3210, and in an embodiment, the penetration lines 3245 may be provided to further penetrate the stack 3210. Each of the semiconductor chips 2200 may further include the input/output pads 2210 (e.g., of FIG. 21), which are electrically connected to the peripheral lines 3110 of the first structure 3100.

Each of the semiconductor chips 2200 may further include an input/output interconnection wiring 3265 electrically connected to the peripheral wirings 3110 of the first structure 3100 and extending into the second structure 3200, and an input/output pad 2210 electrically connected to the input/output interconnection wiring 3265. For example, the input/output interconnection wiring 3265 may extend in a vertical direction from the first structure 3100 through the second structure 3200 to contact the input/output pad 2210.

Referring to FIG. 23, in a semiconductor package 2003A, each of the semiconductor chips 2200 may include a semiconductor substrate 4010, a first structure 4100 on the semiconductor substrate 4010, and a second structure 4200, which is provided on the first structure 4100 and is bonded with the first structure 4100 in a wafer bonding manner.

The first structure 4100 may include a peripheral circuit region, in which a peripheral line 4110 and first junction structures 4150 are provided. The second structure 4200 may include a source structure 4205, a stack 4210 between the first structure 4100 and the source structure 4205, vertical structures 4220 and a separation structure penetrating the stack 4210, and second junction structures 4250, which are electrically connected to the vertical structures 4220 and the word lines WL (e.g., see FIG. 20) of the stack 4210. For example, the second junction structures 4250 may be electrically connected to the vertical structures 4220 and the word lines WL (e.g., of FIG. 20), respectively, through bit lines 4240 electrically connected to the vertical structures 4220, and cell contact plugs electrically connected to the word lines WL (e.g., of FIG. 20). The first junction structures 4150 of the first structure 4100 and the second junction structures 4250 of the second structure 4200 may be in contact with each other and may be bonded to each other. The bonded portions of the first junction structures 4150 and the second junction structures 4250 may be formed of or include, for example, copper (Cu).

Each of the first and second structures 4100 and 4200 and the semiconductor chips 2200 may further include a source structure in an embodiment to be described below. Each of the semiconductor chips 2200 may further include the input/output pads 2210 (e.g., of FIG. 21), which are electrically connected to the peripheral lines 4110 of the first structure 4100.

Each of the semiconductor chips 2200 may further include an input/output pad 2210 and an input/output interconnection wiring 4265 under the input/output pad 2210. The input/output interconnection wiring 4265 may be electrically connected to the peripheral wirings 4110 of the first structure 4100.

The semiconductor chips 2200 of FIG. 22 or 23 may be electrically connected to each other by the connection structures 2400, which are provided in the form of bonding wires. However, in an embodiment, semiconductor chips, which are provided in the same semiconductor package as the semiconductor chips 2200 of FIG. 22 or 23, may be electrically connected to each other by a connection structure including through silicon vias (TSVs).

Though the dummy mold structures are not depicted, part or all of these structures may remain in the second structure 3200 of FIG. 22 and the second structure 4200 of FIG. 23, and the first structure 3100 of FIG. 22 and the first structure 4100 of FIG. 23 may correspond to the peripheral circuit structure in the previous embodiments, while the second structure 3200 of FIG. 22 and the second structure 4200 of FIG. 23 may correspond to the cell array structure in the previous embodiments.

According to an embodiment of the inventive concept, a dummy mold structure may be formed on a scribe line region where alignment keys are formed, and the dummy mold structure may be formed to have substantially the same height as a stack, which is formed on a chip region and has a staircase structure, through substantially the same fabrication process. In the case where a photoresist layer is non-uniformly coated in the process to form the stack, a misalignment issue may be caused by an increased inclination angle of the staircase structure of the stack, but according to an embodiment of the inventive concept, it may be possible to reduce the misalignment issue in an exposure process.

Thus, it may be possible to reduce a failure rate of the semiconductor device and thereby to improve the productivity and reliability of the semiconductor device.

While example embodiments of the inventive concept have been particularly shown and described, it will be understood by one of ordinary skill in the art that variations in form and detail may be made therein without departing from the spirit and scope of the attached claims.

What is claimed is:

1. A method of manufacturing a semiconductor device, comprising:
providing a substrate including a chip region and an edge region around the chip region;
providing an alignment key disposed in the edge region of the substrate;
forming a stack including conductive patterns and interlayer insulating layers, which are vertically and alternatingly stacked on the chip region of the substrate, the stack having a first staircase structure; and
forming a dummy mold structure including dummy insulating layers and sacrificial patterns, which are vertically and alternatingly stacked on the edge region of the substrate, the dummy mold structure overlapping with the alignment key and having a second staircase structure,
wherein the dummy mold structure has the same height as the stack, when measured from a top surface of the substrate.

2. The method of claim 1, wherein the smallest width of the dummy mold structure is larger than the largest width of the alignment key, when measured in a specific direction.

3. The method of claim 1, wherein the first staircase structure comprises first stairs having a first height, and
the second staircase structure comprises second stairs having a second height, which is equal to the first height.

4. The method of claim 3, wherein side surfaces of the first stairs are horizontally spaced apart from each other by a first distance, and
side surfaces of the second stairs are horizontally spaced apart from each other by a second distance, which is smaller than the first distance.

5. The method of claim 3, wherein each of the first stairs comprises at least two of the conductive patterns that are successively stacked, and
each of the second stairs comprises at least two of the sacrificial patterns that are successively stacked.

6. The method of claim 3, wherein an inclination angle of each of the first stairs with respect to a line perpendicular to the top surface of the substrate is substantially equal to that of each of the second stairs.

7. The method of claim 1, wherein the chip region comprises a cell array region and a connection region adjacent thereto, and
the stack has a uniform thickness on the cell array region and has the first staircase structure on the connection region.

8. The method of claim 1, further comprising:
providing a peripheral circuit structure including peripheral circuits integrated on a semiconductor substrate;
forming cell contact plugs connected to the first staircase structure of the stack; and
forming peripheral contact plugs connecting the stack to the peripheral circuits,
wherein the substrate is disposed on the peripheral circuit structure.

9. An electronic system, comprising:
a semiconductor device including:
a substrate including a chip region and an edge region around the chip region;
a stack including conductive patterns and interlayer insulating layers vertically and alternatingly stacked on the chip region of the substrate;
a dummy mold structure including dummy insulating layers and sacrificial patterns vertically and alternatingly stacked on the edge region of the substrate; and
an input/output pad electrically connected to a peripheral circuit; and
a controller, which is electrically connected to the semiconductor device through the input/output pad and is configured to control the semiconductor device,
wherein the stack has a first staircase structure,
the dummy mold structure has a second staircase structure, and
the dummy mold structure has a height, which is substantially equal to a height of the stack, when measured from the substrate.

10. A method of fabricating a semiconductor device, comprising:
alternatingly stacking interlayer insulating layers and sacrificial layers on a substrate to form a layered structure, the substrate including a chip region and an edge region around the chip region, the substrate comprising an alignment key provided in the edge region; and
patterning the layered structure to form a mold structure on the chip region and a dummy mold structure on the edge region,
wherein the patterning of the layered structure comprises repeating a patterning process using the alignment key,
the mold structure has a first staircase structure,
the dummy mold structure overlaps the alignment key and has a second staircase structure, and
the dummy mold structure has the same height as the mold structure, when measured from a top surface of the substrate.

11. The method of claim 10, wherein the smallest width of the dummy mold structure is larger than the largest width of the alignment key, when measured in a specific direction.

12. The method of claim 10, wherein the first staircase structure comprises first stairs having a first set of heights when measured from the top surface of the substrate, and
the second staircase structure comprises second stairs having a second set of heights when measured from the top surface of the substrate, which are respectively equal to the first set of heights.

13. The method of claim 10, wherein a horizontal distance between side surfaces of adjacent stairs of the first stairs is larger than a horizontal distance between side surfaces of adjacent stairs of the second stairs.

14. The method of claim 10, wherein the patterning of the layered structure comprises:
a first step of coating the layered structure with a photoresist layer;
a second step of aligning a photomask using the alignment key;
a third step of exposing and developing the photoresist layer using the photomask to form a photoresist pattern; and
a fourth step of etching a portion of the layered structure using the photoresist pattern as an etch mask to form a first stair on the chip region and a second stair on the edge region.

15. The method of claim 14, wherein the first to fourth steps are repeated to form a plurality of first stairs and a plurality of second stairs, and
as the first to fourth steps are repeated, levels of the first and second stairs are lowered toward the substrate.

16. The method of claim 14, wherein the first to fourth steps are repeated to form a plurality of first stairs and a plurality of second stairs, and
an inclination angle of each of the first stairs is equal to that of each of the second stairs.

17. The method of claim 14, wherein the second step comprises sending light, which passes through the dummy mold structure, to the alignment key and detecting light, which is reflected from the alignment key.

18. The method of claim 14, wherein each of the first and second stairs comprise at least two of the sacrificial layers, which are sequentially stacked.

19. The method of claim 14, wherein the photoresist pattern comprises a first portion, which is formed on the chip region to cover a portion of the layered structure, and a second portion, which is formed on the edge region to cover a portion of the layered structure.

20. The method of claim 14, wherein the first to fourth steps are repeated, and
the photoresist layer on the layered structure has substantially the same thickness in the chip region and the edge region.
